(19) United States
(12) Patent Application Publication
(10) Pub. No.: US 2026/0239561 A1
(43) Pub. Date: Aug. 13, 2026

(54) COLD PLATES FOR USE WITH COMPUTING HARDWARE

(71) Applicant: Nvidia Corporation, Santa Clara, CA (US)

(72) Inventors: Susheela Nanjunda Rao Narasimhan, Fremont, CA (US); Vibin Shalom Simon, San Jose, CA (US); Mohammed Amin Godil, Vancouver, WA (US)

(21) Appl. No.: 19/049,676

(22) Filed: Feb. 10, 2025

(51) Int. Cl. H05K 7/20

(52) U.S. Cl. CPC H05K 7/20254; H05K 7/2039; H05K 7/2079

(57) ABSTRACT

Approaches presented herein provide for receiving liquid coolant into a server or other liquid-cooled computer system at a cold plate having internal channels specifically routed to provide cooling to one or more identified component locations. The cold plate can be the primary source of liquid-cooling for the server, allowing for the removal of extraneous connections and hoses. In one embodiment, a cold plate can be fluidly sealed between an inlet and outlet of coolant into a server to prevent leaks onto damageable components. Compressible bellows extending out from an external surface of a cold plate along the channels can thermally interface with components at different heights. Such a cold plate can include flow control features within the channels, such as to fluidly seal the bellow or to provide microchannels at component interface locations.

### TECHNICAL FIELD

At least one embodiment pertains to regulating temperature in computing hardware, and in particular to using one or more cold plates in such regulating.

### BACKGROUND

Existing computer hardware systems may utilize many devices, hoses, and connections to provide liquid-cooling to components, such as microchips. As the complexity and costs associated with these computer hardware systems continue to increase, it can be increasingly difficult to reduce or eliminate sources of potential liquid leakage, such as are often associated with hoses and connections, inside of these computer hardware systems. It can also be more complicated to provide and manage cooling for these increasingly complex systems.

### BRIEF DESCRIPTION OF THE DRAWINGS

Various embodiments in accordance with the present disclosure will be described with reference to the drawings, in which:

FIGS. 1A-1C illustrate an example data center cooling system subject to improvements described in at least one embodiment;

FIG. 2 illustrates server-level features associated with cold plates for reducing coolant leakage in computer hardware, according to at least one embodiment;

FIG. 3 illustrates rack-level features associated with cold plates for reducing coolant leakage in computer hardware, according to at least one embodiment;

FIGS. 4A-4B illustrate example cold plates to route liquid coolant in computer hardware, according to at least one embodiment;

FIG. 5 illustrates component-level features associated with cold plates for reducing coolant leakage in computer hardware, according to at least one embodiment;

FIG. 6 illustrates an example process that can be performed to use a cold plate adapted to locations of heat generating devices for a liquid-cooled server, according to at least one embodiment;

FIG. 7 illustrates components of a distributed system that can be used to generate, test, and use data center cooling data, according to at least one embodiment;

FIG. 8 illustrates an example data center system, according to at least one embodiment;

FIG. 9 illustrates a distributed system, in accordance with at least one embodiment;

FIG. 10 illustrates a system that includes a client-server network, in accordance with at least one embodiment;

FIG. 11 illustrates a computer network connecting one or more computing machines, in accordance with at least one embodiment;

FIG. 12 is a block diagram that illustrates a computer system, according to at least one embodiment;

FIG. 13 is a block diagram that schematically illustrates a computing system, in accordance with at least one embodiment;

FIG. 14 illustrates an example computing environment, in accordance with at least one embodiment; and

FIG. 15 illustrates a computer system, according to at least one embodiment.

### DETAILED DESCRIPTION

In the following description, various embodiments will be described. For purposes of explanation, specific configurations and details are set forth in order to provide a thorough understanding of the embodiments. However, it will also be apparent to one skilled in the art that the embodiments may be practiced without the specific details. Furthermore, well-known features may be omitted or simplified in order not to obscure the embodiment being described.

Approaches in accordance with various illustrative embodiments provide for using cold plates for cooling of computer hardware, which can provide the additional benefit of reducing or eliminating coolant leaks. In particular, at least one embodiment reduces sources of leakage, part count, need for hoses and connectors, overcrowding, and assembly complexity by receiving liquid coolant into hardware such as a server, for example, at a cold plate having internal channels specifically routed to provide cooling to specific component locations. Such embodiments can be utilized to provide liquid-cooling for an entire server, for example, as well as a barrier to constrain leaks outside a rack, and adaptable liquid channels according to compute device layouts or required coolant flows.

A cooling system for a data center can include at least one cold plate to be positioned in thermal connection with heat generating devices of one or more individual servers of a plurality of servers. Such a cold plate can receive a flow of liquid coolant into the individual servers and provide the routed flow of liquid coolant out of the individual servers. The cold plate can route the received flow of liquid coolant along one or more channels within the cold plate to provide a source of cooling for the heat generating devices at the thermal connections positioned along the channels. The cooling system can include pedestals, such as bellows, extending from the cold plate at the thermal connections to receive the heat generating devices. The cold plate can include an inlet to receive a flow of liquid coolant into the server. The cold plate can include an outlet to send the flow of liquid coolant out of the server.

A cooling system in at least one embodiment can include a cold plate with adapted thermal interfaces for locations of heat generating devices that have changed. A cooling system in at least one embodiment can provide the flow of liquid coolant to additional components of the liquid-cooled server. The channels of such a cold plate can include inserts on at least an interior surface of the cold plate to affect the flow of liquid coolant. For example, the inserts can include a microchannels or fins positioned within the cold plate, such as at thermal connections. The flow of liquid coolant can be sealed from entering the servers out of the cold plate. For example, fluid couplings connected to a fluid source for the cold plate can be positioned outside of the server or computer system. In another example, the cold plate can be formed to have a leak-resistant or leak-proof barrier.

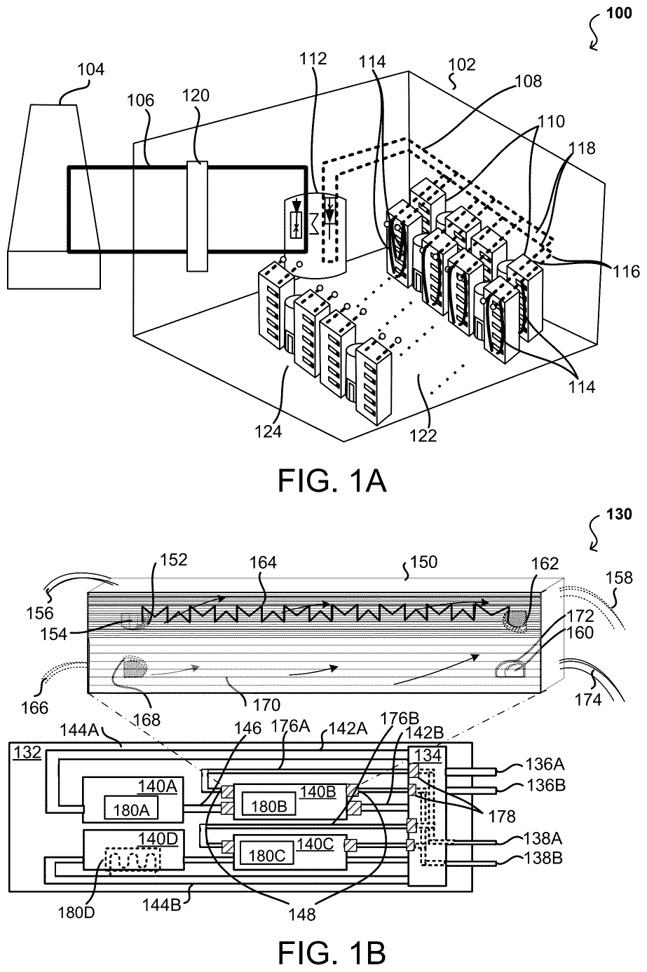

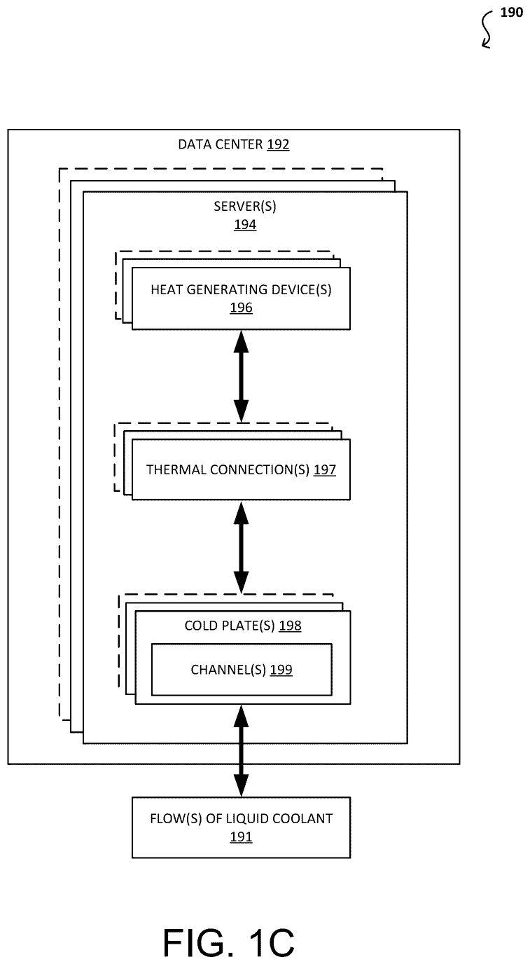

In at least one embodiment, an example data center 100 can be utilized as illustrated in FIG. 1A, which has a cooling system subject to at least some of the improvements described herein. In at least one embodiment, numerous specific details are set forth to provide a thorough understanding, but concepts herein may be practiced without one or more of these specific details. In at least one embodiment, data center cooling systems can respond to sudden high heat requirements caused by changing computing-loads in present day computing components. In at least one embodiment, as these requirements are subject to change or tend to range from a minimum to a maximum of different cooling requirements, these requirements must be met in an economical manner, using an appropriate cooling system. In at least one embodiment, for moderate to high cooling requirements, liquid-cooling system may be used. In at least one embodiment, high cooling requirements are economically satisfied by localized immersion cooling. In at least one embodiment, these different cooling requirements also reflect different heat features of a data center. In at least one embodiment, heat generated from these components, servers, and racks are cumulatively referred to as a heat feature or a cooling requirement as a cooling requirement must address a heat feature entirely.

Previously used liquid-cooling methodologies can allow for leakages on compute tray level due to numerous potential leak points. These leakages can lead to at least electrical shorts, a damage or loss of equipment, downtime in data centers, data, time sensitive financial or other transactions, along with many other difficulties. Additionally, crowded hoses, bulky connections, and other features used in previous methodologies take up valuable space, which reduces airflow and prevents more efficient use of the area serviceable by a compute tray cooling system. Further, kinked hoses can obstruct free flow of cooling liquid, and long runs with multiple hoses, connections, and manifolds can cause fluid pressure drops within the compute tray. The thick hoses which are needed to account for these issues may not be able to fit in a one rack unit (RU) space of a server.

Conversely, as disclosed herein, the use of a single thermo-mechanical adaptable cold plate having routed channels for hotspot cooling can reduce, or eliminate, hoses and quick disconnects (QDs) inside the compute tray. While quick disconnects are good for serviceability, they contribute to higher pressure drops and potential leakage points, complicating the design further. The use of the single thermo-mechanical adaptable cold plate can thereby increase available space, reliability, uptime, and cost savings. The use of the single cold plate, having fluidly sealed internal routed channels for hotspot cooling, can allow for reducing points of potential leakage inside a compute tray to prevent potential damage to compute equipment. Additionally, leaks can be corrected quickly using alternate supply manifolds, such as a secondary rack manifold, and downtime can be reduced to almost zero.

In at least one embodiment, a data center liquid-cooling system is disclosed. In at least one embodiment, this data center cooling system addresses heat features in associated computing or data center devices, such as in graphics processing units (GPUs), in switches, in dual inline memory modules (DIMMs), or central processing units (CPUs), data processing units (DPUs), quantum processing units (QPUs), a plurality of parallel processing units (PPUs), and application-specific integrated circuits (ASICs). QPUs configured to perform one or more operations associated with a quantum algorithm. In some embodiments, each of the one or more QPUs may include a plurality of qubits and the one or more QPUs may be in communication with each other via a quantum channel. In some embodiments, each of the plurality of qubits may include local qubits, global qubits, and/or synchronization qubits. In some embodiments, the local qubits of each QPU may be configured to perform the one or more operations associated with the quantum algorithm on the QPU that the local qubits are associated with. In at least one embodiment, these components may be referred to herein as high heat density computing components. Furthermore, in at least one embodiment, an associated computing or data center device may be a processing card having one or more GPUs, switches, or CPUs thereon. In at least one embodiment, each of GPUs, switches, and CPUs may be a heat generating feature of a computing device. In at least one embodiment, a GPU, a CPU, or a switch may have one or more cores, and each core may be a heat generating feature.

In at least one embodiment, an exemplary data center 100 can be utilized as illustrated in FIG. 1A, which has a cooling system subject to improvements described herein. In at least one embodiment, a data center 100 may be one or more rooms 102 having racks 110 and auxiliary equipment to house one or more servers on one or more server trays. In at least one embodiment, a data center 100 is supported by a cooling tower 104 located external to a data center 100. In at least one embodiment, a cooling tower 104 dissipates heat from within a data center 100 by acting on a primary cooling loop 106. In at least one embodiment, a cooling distribution unit (CDU) 112 is used between a primary cooling loop 106 and a second or secondary cooling loop 108 to enable extraction of heat from a second or secondary cooling loop 108 to a primary cooling loop 106. In at least one embodiment, a secondary cooling loop 108 can access various plumbing into a server tray as required, in an aspect. In at least one embodiment, cooling loops 106, 108 are illustrated as line drawings, but a person of ordinary skill would recognize that one or more plumbing features may be used. In at least one embodiment, flexible polyvinyl chloride (PVC) pipes may be used along with associated plumbing to move fluid along in each provided cooling loop 106, 108. In at least one embodiment, one or more coolant pumps may be used to maintain pressure differences within cooling loops 106, 108 to enable movement of coolant according to temperature sensors in various locations, including in a room, in one or more racks 110, and/or in server boxes or server trays within one or more racks 110.

In at least one embodiment, coolant in a primary cooling loop 106 and in a secondary cooling loop 108 may be at least water and an additive. In at least one embodiment, an additive may be glycol or propylene glycol. In operation, in at least one embodiment, each of a primary and a secondary cooling loops may have their own coolant. In at least one embodiment, coolant in secondary cooling loops may be proprietary to requirements of components in a server tray or in associated racks 110. In at least one embodiment, a CDU 112 is capable of sophisticated control of coolants, independently or concurrently, within provided cooling loops 106, 108. In at least one embodiment, a CDU may be adapted to control flow rate of coolant so that coolant is appropriately distributed to extract heat generated within associated racks 110. In at least one embodiment, more flexible tubing of rack manifold 114 is provided from a secondary cooling loop 108 to enter each server tray to provide coolant to electrical and/or computing components therein. In at least one embodiment, blind-mate fluid connectors may be used to remove a need at least partially for flex tubing. Further, the server trays herein can use flex tubing, hard piping, or a combination of the two.

In at least one embodiment, room manifolds 118 that form part of a secondary cooling loop 108 may include tubing for coolant. Separately, in at least one embodiment, row manifolds 116 may extend from a room manifold 118 having tubing and may also be part of a secondary cooling loop 108 but may include further tubing for coolant. In at least one embodiment, coolant tubing enters racks as part of a secondary cooling loop 108 but may be referred to as rack manifold 114 within one or more racks. In at least one embodiment, row manifolds 116 extend to all racks along a row in a data center 100. In at least one embodiment, plumbing of a secondary cooling loop 108, including room manifolds 118, row manifolds 116, and rack manifolds 114 may be improved by at least one embodiment herein. In at least one embodiment, a chiller 120 may be provided in a primary cooling loop within data center 100 to support cooling before a cooling tower. In at least one embodiment, additional cooling loops that may exist in a primary control loop and that provide cooling external to a rack and external to a secondary cooling loop, may be taken together with a primary cooling loop and is distinct from a secondary cooling loop, for this disclosure.

In at least one embodiment, in operation, heat generated within server trays of provided racks 110 may be transferred to a coolant exiting one or more racks 110 via flexible tubing of a rack manifold 114 of a secondary cooling loop 108. In at least one embodiment, second coolant (in a secondary cooling loop 108) from a CDU 112, for cooling provided racks 110, moves towards one or more racks 110 via provided tubing. In at least one embodiment, second coolant from a CDU 112 passes from one side of the room manifold 118 via tubing, to one side of a rack 110 via a row manifold 116, and through one side of a server tray via different tubing of rack manifold 114. In at least one embodiment, spent or returned second coolant (or exiting second coolant carrying heat from computing components) exits out of another side of a server tray (such as enter left side of a rack and exits right side of a rack for a server tray after looping through a server tray or through components on a server tray). In at least one embodiment, spent second coolant that exits a server tray or a rack 110 comes out of different side (such as exiting side) of tubing of rack manifold 114 and moves to a parallel, but also exiting side of a row manifold 116. In at least one embodiment, from a row manifold 116, spent second coolant moves in a parallel portion of the room manifold 118 and is going in an opposite direction than incoming second coolant (which may also be renewed second coolant), and towards a CDU 112.

In at least one embodiment, spent second coolant exchanges its heat with a primary coolant in a primary cooling loop 106 via a CDU 112. In at least one embodiment, spent second coolant may be renewed (such as relatively cooled when compared to a temperature at a spent second coolant stage) and ready to be cycled back to through a secondary cooling loop 108 to one or more computing components. In at least one embodiment, various flow and temperature control features in a CDU 112 enable control of heat exchanged from spent second coolant or flow of second coolant in and out of a CDU 112. In at least one embodiment, a CDU 112 may be also able to control a flow of primary coolant in primary cooling loop 106.

In at least one embodiment, exemplary server-level features 130 can be utilized as illustrated in FIG. 1B, which is associated with a cooling system subject to improvements described herein. In at least one embodiment, server-level features 130 as illustrated in FIG. 1B can be associated with cold plates for reducing coolant leakage. In at least one embodiment, server-level features 130 include a server tray or box 132. In at least one embodiment, a server tray or box 132 includes a server manifold 134 to be intermediately coupled between provided cold plates 140A-140C of a server tray or box 132 and rack manifolds 114 of a rack 110 hosting a server tray or box 132. In at least one embodiment, a server tray or box 132 includes one or more cold plates 140A-140C associated with one or more computing or data center components or devices 180A-180C. In at least one embodiment, the one or more cold plates 140A-140C may be intermediately coupled between an external coolant source, such as the rack manifolds 114 of a rack 110 hosting a server tray or box 132, and provided components of the server tray or box 132 or the rack 110. In at least one embodiment, one or more cold plates 140A-140C may be dual-cooling-enabled cold plates having a first distinct path 164 capable of cooling using a first coolant and second a second distinct path 170 capable of cooling using a second coolant concurrently with a first coolant or at separate times. In at least one embodiment, such first distinct path 164 and second distinct path 170 are fins, tubes, or microchannels.

In at least one embodiment, at least one heat sink 140D includes fins and is exposed to an environment of a server tray or box 132 so that cold air from a cold aisle 122 can be used as cooling media through such fins to cool a heat sink 140D before such cold air exits to a hot aisle 124. In at least one embodiment, an associated computing device 180D benefits from cooling provided by such heat sink 140D (that need not have a cold plate or coolant for cooling). In at least one embodiment, therefore, cooling media may be air or single-phase fluid. In at least one embodiment, at least one thermal test vehicle (TTV) 180D is illustrated to indicate that testing of a data center cooling system may be performed using cold plates for reducing coolant leakage for data center cooling systems.

In at least one embodiment, one or more server-level cooling loops 144A, 144B may be provided between a server manifold 134 and one or more cold plates 140A-140C, for single or dual-cooling-enabled cold plates. In at least one embodiment, one or more server-level cooling loops 144A, 144B may be provided between one or more cold plates 140A-140C and an external source, such as the rack manifolds 114, for single or dual-cooling-enabled cold plates. In at least one embodiment, each server-level cooling loop 144A, 144B includes a coolant line 142A, 142B. In at least one embodiment, when there are series configured cold plates 140A, 140B, an intermediate line 146 may be provided. In at least one embodiment, however, for cold plates to reduce coolant leakage, distinct fluid paths, via provided lines 176A, may be established to pass a first coolant through first inlet and outlets 136A, 136B and a second coolant through second provided inlet and outlet lines 138A, 138B. In at least one embodiment, there may be separate server rack cooling manifolds for each type of coolant used.

In at least one embodiment, one or more cold plates 140A-140C may be only single-coolant-enabled cold plates or only dual-coolant-enabled cold plates. In at least one embodiment, one or more cold plates 140A-140C, when adapted for dual purpose, may support distinct ports and channels for a first secondary coolant of a secondary cooling loop and for a second secondary coolant (or local coolant) circulated from a local coolant source. In at least one embodiment, a first secondary coolant for cooling may be provided to a server manifold 134 or one or more cold plates 140A-140C via provided first inlet and outlets 136A, 136B. In at least one embodiment, a second secondary coolant may be provided to a server manifold 134 or one or more cold plates 140A-140C via provided second inlet and outlet lines 138A, 138B. In at least one embodiment, all such manifolds, cold plates, lines, or loops may be terminated using flow controllers having mechanical coupling and electrical coupling features. In at least one embodiment, electrical coupling features enable at least one processor to control aspects of a flow controller for cold plates to reduce coolant leakage.

In at least one embodiment, a server tray or box 132 is an immersive-cooled server tray that may be flooded by fluid. In at least one embodiment, a fluid for an immersive-cooled server tray may be a dielectric engineered fluid capable of being used in an immersive-cooled server. In at least one embodiment, a secondary coolant or local coolant may be used to cool engineered fluid. In at least one embodiment, a local coolant may be used to cool engineered fluid when a primary cooling loop associated with a secondary cooling loop circulating a secondary coolant has failed or is failing. In at least one embodiment, at least one cold plate, therefore, has ports for a secondary cooling loop and for a local coolant cooling loop from a local coolant source that is part of a system adapted for cold plates to reduce coolant leakage. In at least one embodiment, such a cold plate can support a local coolant that may be activated in an event of a failure in a primary cooling loop.

In at least one embodiment, at least one dual-cooling cold plate 140B, 150 may be configured to work alongside regular cold plates 140A, 140C. In at least one embodiment, a three-dimensional (3D) blow-up illustration (cold plate 150) provides internal detail of at least some features that may be included in a dual-cooling cold plate or a regular cold plate. In at least one embodiment, a tear-through of a cold plate 150 illustrates microchannels 170 and a distinct section for the first distinct path 164 as tubes functioning as heat dissipation features, as illustrated in FIGS. 1A, 1B. In at least one embodiment, a distinct second section may be provided side-by-side and have heat dissipation features in at least a part of such a cold plate. In at least one embodiment, a local coolant-enabled cold plate may have only tubes as the first distinct path 164 and no microchannels as the second distinct path 170 therein.

In at least one embodiment, a dual-cooling cold plate 150 has distinct paths 164, 170 for secondary coolant of a secondary cooling loop, for local coolant of a local cooling loop, and for local coolant from a local coolant source. In at least one embodiment, in a use case of an immersive-cooled server, fluid that may be a dielectric engineered fluid may be adapted for both, a cold plate application and an immersive-cooled server tray application. In at least one embodiment, some microchannels 170 are paths provided by fins or other such aspects that raise internally and perpendicularly to a base of a cold plate section, and that have gaps therebetween for coolant or fluid flow. In at least one embodiment, some microchannels 170 are fluid pathways in a different cold plate section of a cold plate 150.

In at least one embodiment, reference to a cold plate, along with its dual-cooling features, may imply a reference to a cold plate that can support at least two types of cooling loops, unless otherwise stated. In at least one embodiment, both types of cold plates receive at least local coolant for cooling, but one type can support both, a secondary cooling loop or a local cooling loop and local coolant from a local coolant source. In at least one embodiment, a standard coolant, such as facility water, may be used in a secondary cooling loop.

In at least one embodiment, a fluid or local coolant may only support cold plate usage and may not be available for immersive cooling. In at least one embodiment, each type of cold plate receives local coolant that may be associated with different secondary or local coolant from respective local cooling loops or other cooling loops interfacing with a primary cooling loop. In at least one embodiment, in situations where different fluids (such as secondary coolants and local coolants) are used in a data center cooling system, then a secondary or local cooling loop may be suited for a dual-cooling cold plate, along with local coolant. In at least one embodiment, secondary or local coolant may be supported by cold plates able to reduce coolant leakage, so that different channels may be used for each of a local coolant and for different secondary coolants.

In at least one embodiment, a dual-cooling cold plate 150 is adapted to receive two types of fluids (such as a secondary coolant and a local coolant) and to keep two types of fluids distinct from each other via their distinct ports 152, 172, 168, 162 and their distinct paths 164, 170, such as by distinct sections separated by gaskets and plates (such as in a gasket type cold plate). In at least one embodiment, fluid lines 156, 158, 166, 174 are associated with such ports 152, 162, 168, 172, via respective flow controllers. In at least one embodiment, each distinct path is a cooling or flow path. In at least one embodiment, fluid (such as a local coolant or a secondary coolant) from a local coolant source and a secondary coolant may be provided simultaneously to address additional cooling requirements. In at least one embodiment, distinct ports and paths may support different sources that may be provided to address a higher cooling requirement from an associated computing device.

In at least one embodiment, a dual-cooling cold plate 150 includes ports 152, 162 to receive a local coolant into a cold plate 150, to enable such local coolant to pass through a cold plate 150, and to enable such local coolant to pass out of a cold plate 150. In at least one embodiment, a dual-cooling cold plate 150 includes ports 168, 172 to receive a secondary coolant into a cold plate 150, to enable such secondary coolant to pass through a cold plate 150, and to pass a secondary coolant out of a cold plate 150. In at least one embodiment, provided ports 152, 162 may have valve covers 154, 160 that may be directional to enable flow of local coolant or secondary coolant through a cold plate 150.

In at least one embodiment, provided valve covers 154 are mechanical features of associated flow controllers that also have corresponding electronic features (such as at least one processor to execute instructions stored in associated memory and to control mechanical features for associated flow controllers). In at least one embodiment, sensors can be used to provide feedback to adjust inlet local coolant through a cold plate.

In at least one embodiment, each valve may be actuated by an electronic feature of an associated flow controller. In at least one embodiment, electronic and mechanical features of provided flow controllers are integrated. In at least one embodiment, electronic and mechanical features of provided flow controllers are physically distinct. In at least one embodiment, reference to flow controllers may be to one or more of provided electronic and mechanical features or to their union but is at least in reference to features enabling control of flow of coolant or fluid through each cold plate or an immersion-cooled server tray or box.

In at least one embodiment, electronic features of provided flow controllers receive control signals and assert control over mechanical features. In at least one embodiment, electronic features of provided flow controllers may be actuators or other electronic parts of other similar electromechanical features. In at least one embodiment, flow pumps may be used as flow controllers. In at least one embodiment, impellers, pistons, or bellows may be mechanical features, and an electronic motor and circuitry form electronic features of provided flow controllers. In at least one embodiment, circuitry of provided flow controllers may include processors, memories, switches, sensors, and other components, altogether forming electronic features of provided flow controllers.

In at least one embodiment, provided ports 152, 162, 168, 172 of provided flow controllers are adapted to either allow entry or to allow egress of an immersive fluid. In at least one embodiment, flow controllers 148 may be associated with fluid lines 176A, 176B (also 156, 158) that enable entry and egress of a local coolant to a cold plate 140A-140C. In at least one embodiment, other flow controllers may be similarly associated with coolant lines 142A, 142B (also 166, 174), or intermediate line 146, to enable entry and egress of a secondary coolant to a cold plate 140B, 140C.

In at least one embodiment, a local coolant enters provided fluid lines 176A, 176B via dedicated second inlet and outlet lines 138A, 138B. In at least one embodiment, a server manifold 134 or a cold plate 140A-140C is adapted with channels therein (illustrated by dotted or broken lines) to support distinct paths to distinct fluid lines 176A, 176B (also 156, 158) and to any remaining loops 144A, 144B that are associated with secondary coolant inlet and outlet lines 138A, 138B. In at least one embodiment, there may be multiple server manifolds or cold plates to support local coolant and a distinct secondary coolant. In at least one embodiment, there may be multiple server manifolds or cold plates to support entry and egress, distinctly, for each of a local coolant and of a secondary coolant. In at least one embodiment, a local coolant is singularly used without a secondary cooling loop.

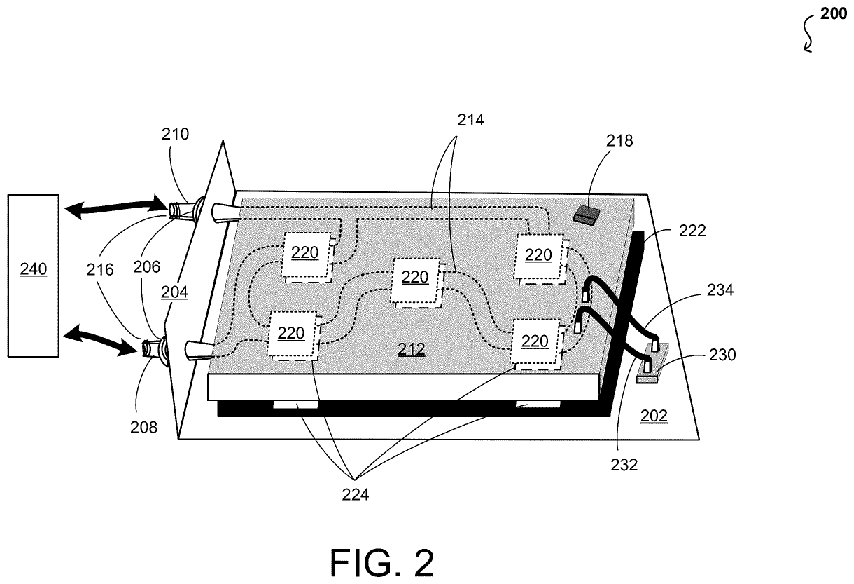

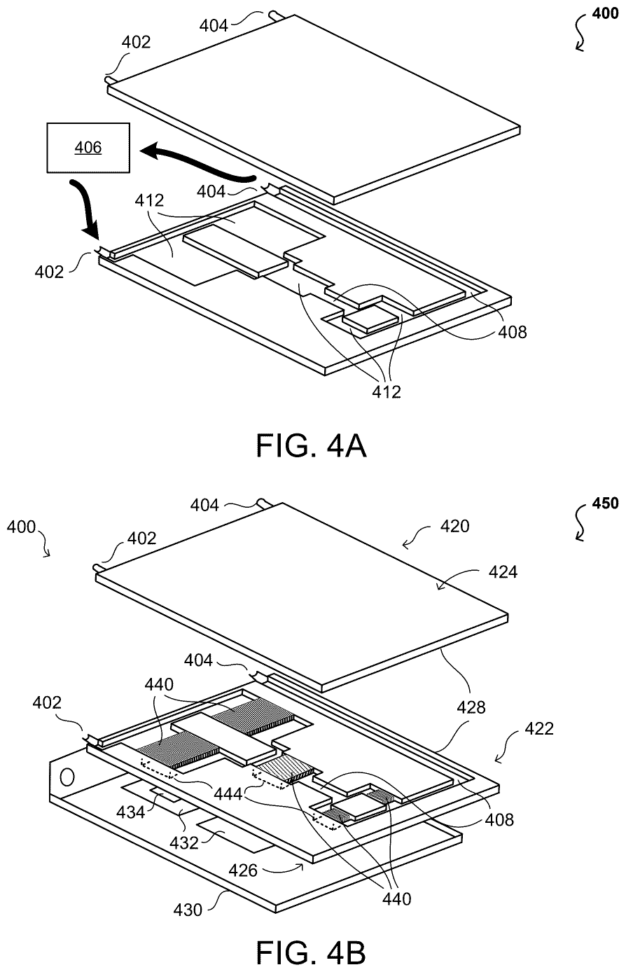

In at least one embodiment, an exemplary data center cooling system 190 can be utilized as illustrated in FIG. 1C, according to at least one embodiment. In at least one embodiment, a data center cooling system 190 includes a data center 192, such as the data center 100 as illustrated in FIG. 1A. The data center 192 may have a plurality of servers 194, such as the server-level features 200 as illustrated in FIG. 2. The individual servers 194 may have a plurality of heat generating devices 196, such as a circuit board, networking card, storage drive, compute block, processing unit, or other suitable devices. The individual servers 194 may include at least one cold plate 198 able to be positioned in thermal connection 197 with the heat generating devices 196, such as the cold plate 400 as illustrated in FIG. 4A or FIG. 4B.

In an embodiment, one or more of the servers may include only one cold plate 198 that provides a source of cooling from liquid of the entire server. The cold plates 198 may receive a flow of liquid coolant 191 into the individual servers 194, such as without a manifold or couplings from the coolant source to the cold plate 198 being located inside of the server. The cold plate 198 may route the received flow of liquid coolant 191 along one or more channels 199 within the cold plate 198 for cooling of the heat generating devices 196 at the thermal connections 197 positioned along the channels 199. The cold plates 198 may then provide the routed flow of liquid coolant 191 out of the individual servers 194. The cold plate 198 may be in thermal connection with one or more of the heat generating devices 196 of the individual servers 194, such as though a surface of the cold plates 198. The cold plates 198 may be able to transfer the flow of cooling fluid with one or more fluidly connectable components of the individual servers 194. The data center cooling system 190 may provide cooling by using the cold plates 198 as a source of cooling to one or more of the heat generating devices 196 via the thermal connection and by using the cold plates 198 to distribute the flow of cooling fluid to one or more of the fluidly connectable components via fluid transfer.

FIG. 2 illustrates server-level features 200 associated with cold plates for reducing coolant leakage in computer hardware for data center cooling systems. In at least one embodiment, a data center cooling system, therefore, includes a server tray or box 202 having a surface 204 with one or more external flow controllers 206 mounted removably thereon to transfer a flow of liquid coolant. In at least one embodiment, multiple external flow controllers 206 may be provided so that entry of coolant occurs through one of such flow controllers and egress of coolant occurs through a different one of such flow controllers. In at least one embodiment, each external flow controller 206 includes an associated coupling 216. In at least one embodiment, an associated coupling 216 includes push-coupling or threaded-coupling features to enable an external flow controller 206 to fluidly communicate with one or more of an external liquid coolant source 240. In at least one embodiment, a data center cooling system may include at least one cold plate 212 to receive a flow of liquid coolant into the server tray or box 202, which may be able to prevent or reduce leaks of coolant in the server tray or box 202. One or more external flow controllers 206 may also be associated with the cold plate 212, such as mounted inside the cold plate 212. In at least one embodiment, the external flow controllers 206 may be adapted to close concurrently when a server tray or box 202 is to be disconnected from a rack. In at least one embodiment, the external flow controllers 206 may be adapted to close separately depending on a local or a secondary coolant used, which allows for maintenance of a secondary cooling loop while a local cooling loop is operational to provide redundancy in operations. In at least one embodiment, this prevents leaks when removing a server tray or box from an external coupling, or prevents leaks when removing the cold plate 212 from the server tray or box 202. One or more leakage sensors may also be included and may be associated with at least one of the server tray or box 202, the cold plate 212, or other components.

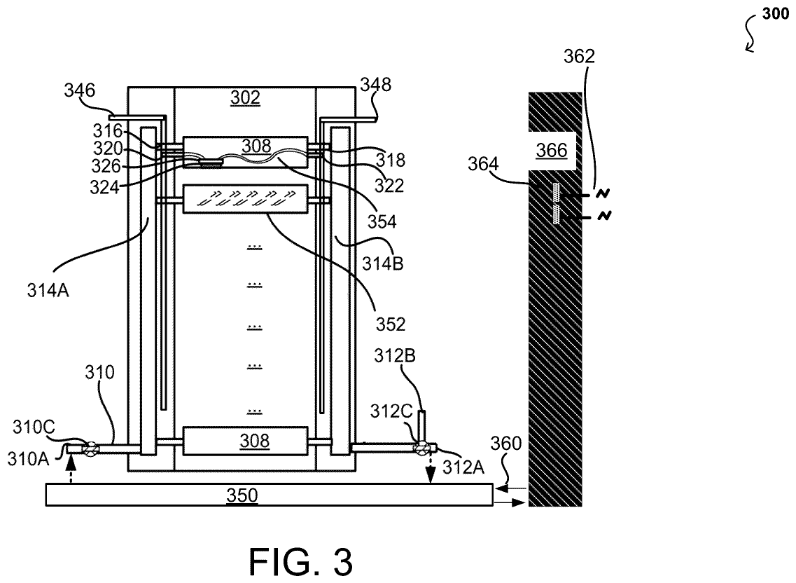

In at least one embodiment, the flow of coolant enters the server tray or box 202 via the external flow controller 206 that may be coupled, at its associated coupling 216, to a rack-side flow controller of a rack cooling manifold, as illustrated in FIG. 3, and then to the one or more cold plates 212 via a coolant inlet 208, to cool an associated computing device 224 or other heat generating device. The coolant inlet 208 may be a part of the cold plate 212 and the connection with the external liquid coolant source 240 of the coolant flow may be positioned outside of the server tray or box 202. In at least one embodiment, the flow of coolant exits the server tray or box 202 from the one or more cold plates 212 via a coolant outlet 210, and then to the external flow controller 206 that may be coupled, at its associated coupling 216, to a rack-side flow controller of a rack cooling manifold, as illustrated in FIG. 3. The coolant outlet 210 may be a part of the cold plate 212 and the connection with the external liquid coolant source 240 of the coolant flow may be positioned outside of the server tray or box 202. In at least one embodiment, secondary coolant flows through the external flow controllers 206, the coolant inlet 208, coolant outlet 210, and the cold plate 212 that may be an inlet server cooling manifold. In at least one embodiment, more than one of the cold plate 212 may be used so that multiple server-level cooling loops may be established without further flow controllers for each server-level cooling loop. In at least one embodiment, at least two distinct server-level cooling loops are included. In at least one embodiment, heat is removed from the associated computing device 224 by transfer to a secondary coolant. The computing devices 224 may be positioned on the circuit boards 222, and may include an application specific integrated circuit (ASIC), an integrated circuit (IC) chip, a CPU, a GPU, a microprocessor, a FPGA, a collection of logic gates or transistors, resistors, capacitors, inductors, diodes, or the like. In at least one embodiment, coolant from an external liquid coolant source 240 enters the server tray or box 202 to the cold plate 212. The cold plates 212 may be able to receive a flow of liquid coolant, such as from the external liquid coolant source 240. The cold plates 212 may then provide a source of cooling such as to the computing device 224, and distribute the flow of liquid coolant, such as to additional fluidly connected components 230 of the server tray or box 202, using internal channels 214.

In at least one embodiment, however, a single cold plate 212 having internal channels 214 for inlet and for outlet may be used. This configuration provides a flexible internal channel routing, enabling the adaptation of the cold plate to different board layouts and optimizing fluid flow to various components. In at least one embodiment, coolant may flow out from the cold plate 212 and be removed from the server tray or box 202, such as to a rack outlet cooling manifold at an outlet side as the external liquid coolant source 240. The internal channels 214 of the cold plate 212 may route the coolant between the coolant inlet 208 and the coolant outlet 210, as well as along adaptable paths that may be adaptable to locations of thermal connections 220 with the computing devices 224. The internal channels 214 may be carved, placed, or otherwise formed in the interior of the cold plate 212, such that the coolant fluid is prevented from leaking from the internal channels 214 and into the server tray or box 202. For example, the cold plate 212 and/or the internal channels 214 may be sealed or brazed together to close openings that may have allowed for leaks inside of the server tray or box 202, therefore preventing potential damage. In an embodiment, the cold plate 212 and/or the internal channels 214 may be leak-proof and/or leak resistant. The thermal connections 220 may be positioned at the locations of the computing device 224 along the internal channels 214 to provide hotspot cooling to the computing device 224. The thermal connections 220 may include pedestals, compressible bellows, microchannels, fins, or tubes, such as to affect the flow of the coolant or to provide a source of cooling to the computing device 224.

In at least one embodiment, if serial cold plates are used in a server-level cooling loop, then an intermediate coolant inlet may enable a flow of coolant from a first cold plate to a second cold plate that is associated with a different computing device, such as using internal channels 214. In at least one embodiment, a coolant outlet 210 enables coolant to be passed back to cold plate 212 that may act as an outlet server cooling manifold. In at least one embodiment, however, a single cooling cold plate having channels for inlet and for outlet may be used with one or more external flow controllers 206. In at least one embodiment, each such coolant tube or line may be associated with a flow controller and/or a leak sensor so that leaks are prevented upon disconnection of any such coolant tube or line. In at least one embodiment, a secondary coolant may be PG-25®, deionized water, and HC-30®.

In at least one embodiment, a flow of liquid coolant is received into the cold plate 212 which may act as an inlet manifold. In at least one embodiment, the flow of liquid coolant may enter into the first cold plate 212 from the external liquid coolant source 240, to provide a source of cooling to the computing devices 224 on circuit board 222. An intermediate flow of liquid coolant may be provided through inlet connection 232 to enter into a fluidly connected component 230 of the server tray or box 202. In at least one embodiment, heat is removed from the computing devices 224 by transfer to a flow of liquid coolant through a surface of the cold plate 212 between the computing devices 224 and the flow of liquid coolant. The computing devices 224 may also be positioned on an exterior thermal transfer surface of the cold plate 212 separated from the flow of liquid coolant, in contact with an exterior thermal transfer surface of the cold plate 212 separated from the flow of liquid coolant, or otherwise in thermal connection with the cold plate 212 and also out of contact with a flow of liquid coolant. In at least one embodiment, a return flow of liquid coolant may be sent back through outlet connection 234 from the fluidly connected component 230 to the cold plate 212 that may act as an outlet manifold, such as to external liquid coolant source 240.

In at least one embodiment, one or more sensors 218 may be coupled to a processor that is external to such an external flow controller 206. In at least one embodiment, multiple sensors 218 communicate to an external processor that may be a part of a BMS or a building management system. In at least one embodiment, a control unit (such as a last server tray or box 308 of a rack 302 in FIG. 3) may be provided as a server tray or box form-factor within a rack to control all flow controllers within a rack. In at least one embodiment, therefore, a processor may be adapted to receive input from the sensor 218. In at least one embodiment, such input or sensor input may be about the external flow controller 206 or cold plate 212. In at least one embodiment, sensor input is as to temperature, flow rate, flow volume, or pressure associated with a primary or secondary coolant through one or more external flow controllers 206. In at least one embodiment, an action of a processor may be triggered based in part on such input from the sensor 218. In at least one embodiment, such an action may be an output from a processor to a primary flow controller, such as reference numeral 364 in FIG. 3.

FIG. 3 illustrates rack-level features 300 associated with using cold plates for reducing coolant leakage in computer hardware for data center cooling systems. In at least one embodiment, such rack-level features 300 include one or more racks 302 in one or more rows. In at least one embodiment, each row may be associated with its own cooling manifold 350 that is associated with a secondary coolant for dual purpose cold plates, although only a secondary coolant-based cooling or only a local coolant-based cooling may be enabled for one or all of such racks 302 in FIG. 3 using dedicated cooling manifolds 346, 348.

In at least one embodiment, some server trays or boxes 308 may be associated with secondary coolant-based cooling, while other server tray or boxes may be associated with a local coolant-based cooling and some others may be associated with two-phase cooling. In at least one embodiment, in each such case, server trays or boxes 308 are associated with a CDU 366 via lines 362, where such a CDU 366 supports using cold plates for reducing coolant leakage in computer hardware. In an embodiment, coolant may flow 360 between the CDU 366 and a coolant source via lines 362 using primary flow controllers 364.

In at least one embodiment, flow paths may be enabled to a dual-purpose cold plate 326, through one or more rack cooling manifolds 314A, 314B or 346, 348 that is within a rack 302. In at least one embodiment, a singular rack cooling manifold may support entry and egress of a secondary coolant and a separate rack cooling manifold may support entry and egress of a local coolant. In at least one embodiment, however, separate rack cooling manifolds 314A, 314B may be used for each of entry and of exit of each of such secondary coolant and local coolant depending on if both are used or if each is used independently.

In at least one embodiment, such a dual-purpose cold plate 326, which may reduce coolant leakage, is associated with a computing device 324 that may have a cooling requirement that may be addressed by a secondary coolant, a local coolant, or a combination of coolants. In at least one embodiment, such a flow path allows secondary or local coolant from a row cooling manifold 350 to enter into and exit from one or more rack cooling manifolds 314A, 314B. In at least one embodiment, secondary or local coolant may flow 360 between a row cooling manifold 350 and the CDU 366. In at least one embodiment, such secondary coolant flows through a row cooling manifold 350, through an inlet 310A of a rack 302, through a flow controller 310C adapted to switch between at least two coolant paths (or a coolant path and a local coolant path), through an inlet 310, and into a rack cooling manifold 314A. In at least one embodiment, such secondary or local coolant enters a cold plate 326 and addresses one cooling requirement associated with a cold plate 326 and/or its associated computing device 324. In at least one embodiment, a separate flow controller than an illustrated flow controller 310C may be used for local coolant.

In at least one embodiment, secondary or local coolant flows through a further inlet 316 of a server tray or box 308, to a cold plate 326 of an associated computing device 324, out of an outlet 318 of a server tray or box 308, through a rack cooling manifold 314B, into a further outlet 312, through another flow controller 312C, and out of an outlet line 312A to a row cooling manifold 350 that may be a same or a different row cooling manifold than an inlet side row cooling manifold. Further, a row cooling manifold 350 or a rack cooling manifold 314A, 314B may have different channels therein to support inlet and outlet flows.

In at least one embodiment, for a dual cooling cold plate or a single coolant cold plate, a local coolant may be caused to occur via different flow paths, such as an inlet or inlet lines from a distinct inlet manifold 346 provided at a top of a rack 302, through a channel of a rack cooling manifold 314A or a dedicated local coolant manifold 346, through direct lines 320, 354, 322 to a cold plate 326, and out of outlet lines of a further distinct manifold 348 at a top of a rack 302.

In at least one embodiment, a rack 302 can, therefore, include distinct local coolant flow paths rather than secondary coolant flow paths. In at least one embodiment, such direct lines may be available within each of a server trays or boxes 308 of a rack 302 and may also be available within an immersive server 352 of a rack 302. In at least one embodiment, such local coolant enters a cold plate 326 and addresses a second cooling requirement that may be associated with a cold plate 326 and/or its associated computing device 324. In at least one embodiment, a cold plate 326 is either a coolant cold plate, a local coolant cold plate, or a dual cooling cold plate supporting secondary coolant and local coolant, with a cold plate for reducing coolant leakage.

FIG. 4A illustrates an example cold plate 400 to route liquid coolant in computer hardware such as for a computer system, according to at least one embodiment. In at least one embodiment, the cold plate 400 may have, at least one inlet 402 to receive from an external liquid coolant source 406, one or more internal paths 408 from the at least one inlet 402 to compute device interface locations 412, and at least one outlet 404 from the one or more internal paths 408 to the external liquid coolant source 406. The inlet 402 and the outlet 404 may be source fluid adapters. The source fluid adapters may enable receipt and egress of the liquid coolant between the cold plate 400 and at least an external liquid coolant source 406 or interface, such as the cooling tower or primary cooling loop illustrated in FIG. 1A, or the rack cooling manifold or the CDU illustrated in FIG. 3. The inlet 402 and the outlet 404 may transfer the coolant with the external liquid coolant source 406 outside of a server the cold plate 400 is located in, such that the connections between the cold plate 400 and the external liquid coolant source 406 are outside of the server. The inlet 402 and the outlet 404 may be integrated with the cold plate 400 as a single piece, or may be sealed with the cold plate 400, such as to provide a fluidly sealed route for liquid coolant.

In at least one embodiment, coolant, or other fluid flows, as indicated by the arrows, into inlet 402, through the cold plate 400, and out of the outlet 404, transferring fluid with the external liquid coolant source 406. The cold plate 400 may include the internal paths 408 connected to inlet 402 and the outlet 404, such as to transfer the flow through the cold plate 400. In at least one embodiment, the flow of the coolant refers to flow rate or flow volume of the coolant in cold plate 400 or into or out of the cold plate 400. In at least one embodiment, the coolant is in a dynamic state and is continuously moving through the cold plate 400. The internal paths 408 of the cold plate 400 may be adapted to a layout of compute devices for a server. For example, multiple cold plates 400 with different internal paths 408 may be selected from based on the intended compute device layout, and/or other considerations, for a server. In another example, the internal paths 408 of the cold plate 400 may be designed, built, or otherwise provided based on an existing compute device layout, and/or other considerations, of a server. In an embodiment, one or more of the cold plate 400, the inlet 402, the outlet 404, and/or the internal paths 408 may be fluidly sealed for coolant through a server to prevent coolant leakage, such as having sealed or routed from the inlet 402, through the internal paths 408, and to the outlet 404. In another embodiment, at least the cold plate 400, the inlet 402, the outlet 404, and/or the internal paths 408 may be provided as a single structure or device being fully enclosed except opening of the inlet 402 and the outlet 404 to receive coolant from a external liquid coolant source 406.

As power levels rise, more space is taken up by components and cooling needs increase for computer hardware, additional distribution and larger hoses are required to maintain efficient performance. Accordingly, more substantial cooling fluid delivery hardware may be required, such as thicker hoses and connections for the higher flow rate, where the hoses have larger diameters and bend radiuses, utilizing even more space. The use of the cold plate 400 with adaptable sealed internal paths 408 can reduce the space required by eliminating or reducing these features in the server as well as reducing coolant leakage. Using only a single one of the cold plates 400 to provide a source of cooling from the flow of fluid coolant for an entire server allows for number of internal fluid connections to be reduced or eliminated, freeing up space, reducing potential leakage points, and lowering costs. Any fluid connections, such as connectors and hoses, that are used to provide the flow of fluid coolant to other components directly from the cold plate 400 can be smaller, more malleable, and less expensive, and may be easier to route around the system rather than larger connection parts that may be required for systems that do not utilize the cold plate 400. In an embodiment, a system may have more than one of the cold plates 400 with adaptable sealed internal paths 408. For example, the cold plates 400 with adaptable sealed internal paths 408 may be connected to each other, such as in series, parallel, or other configurations, while also providing a source of cooling to other components. For example, the one or more cold plates may be able to be connected using at least one daisy chain-style connection including a plurality of hoses and connectors. In an embodiment, the more than one cold plates 400 may be connected to each other and also connected to one or more external coolant fluid sources or interfaces.

FIG. 4B illustrates an example cold plate 400 to route liquid coolant in computer hardware, such as for a computer system 450, according to at least one embodiment. In at least one embodiment, the cold plate 400 may, different from the embodiment in FIG. 4A, be associated with a server tray or box 430. In an example, the cold plate 400 may include one or more fluid connections with external liquid coolant sources 406, and may include one or more fluid connections with other components. As shown in FIG. 4A, the cold plate 400 may receive a flow of coolant into the server tray or box 430 at the inlet 402 and may distribute the flow of coolant out of the server tray or box 430 from the outlet 404. The flow of coolant from the outlet 404 may be provided to one or more other components, such as a manifold. The server tray or box 430 may also include compute devices 434 of circuit boards 432, such as printed circuit boards (PCB) or a collection of PCBs, which are provided cooling from the cold plate 400 or include components which are provided cooling from the cold plate 400. The cold plate 400 may be provided, such as before being secured to the server tray or box 430, in two or more separate portions 420, 422. For example, the cold plate 400 may have the portion 420 as a first section and the portion 422 as a second section. As illustrated in FIG. 4B, the portion 420 may be an upper section or cover and the portion 422 may be a lower section or base. The portions 420, 422 may include the inlet 402, the outlet 404, the internal paths 408, the compute device interface locations 412 or other suitable features. The cold plate 400 may have one or more edges 428 able to be connected to form a cold plate as a single device, which may be fluidly sealed from the inlet 402 to the outlet 404. The edges may be associated with the separate portions 420, 422, such as to allow for the two separate portions 420, 422 to be combined into the single cold plate 400. The edges 428 may be joined by being brazed, diffusion bonded, sealed, or combined in another suitable manner. The cold plate 400 and/or the surfaces 424, 426 with joined edges 428 may acts as a liquid-proof or leak-resistant barrier.

The cold plate 400 may have one or more exterior thermal transfer surfaces 424, 426 or cooling surfaces that can be used to provide a source of cooling by thermal transfer with coolant or other fluid, such as on one or more of the separate portions 420, 422. The exterior thermal transfer surfaces 424, 426 of the cold plate 400 may provide a source of cooling to a compute device 434 of a circuit board 432 associated with the cold plate 400, such as positioned on the exterior thermal transfer surface 424, 426. There may be more than one of the compute device 434 that receive a source of cooling from the cold plate 400, rather than the flow of liquid coolant, and some components may receive both the source of cooling and the flow of liquid coolant. For example, the compute devices 434 may be any hardware which has a heat generating feature, such as a circuit board, networking card, storage drive, compute block, processing unit, or other component. In an example, the compute devices 434 may be one or more compute devices, compute hardware, processing units, or other suitable hardware. In an embodiment, the compute device 434 may be a distinct assembly of hardware components that can be easily added, removed, or replaced in the computer system 450 to allow for the performance of various computations. The cold plate 400 may, therefore, act as a cooling source for some components as a traditional cold plate and may also act to receive the flow of fluid coolant from a source and distribute the flow to components.

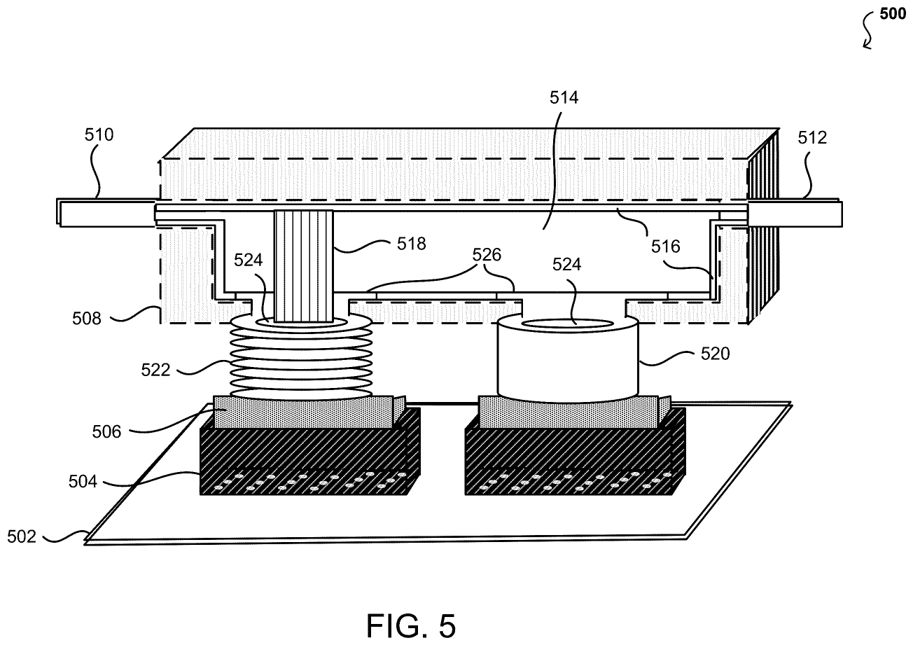

The cold plate 400 may include one or more inserts 440, such as microchannels, fins, or coolant tubing, or other suitable devices, along the internal paths 408. The inserts 440 may be able to affect or influence the flow of the coolant, or affect the cooling provided by the cold plate 400. The inserts 440 may be positioned at the compute device interface locations 412, such as to affect the cooling provided by the cold plate 400 to the compute devices 434. For example, the inserts 440 positioned at the compute device interface locations 412 may include microchannels or fins to increase the cooling provided to the compute devices 434. The cold plate 400 may include one or more projections 444, such as the pedestals 520 and bellows 522 as illustrated in FIG. 5. The projections 444 may be located at the compute device interface locations 412, such as allow a cooling surface of the cold plate 400 to be closer to the compute devices 434. In one embodiment, compressible bellows extending out from a surface of the cold plate 400 along the internal paths 408 or channels can thermally interface with compute devices 434 at different heights. The cold plate and the inserts and/or the projections 444 may include at least two different materials. One or more of the inserts 440 and/or the projections 444 may include copper. The cold plate 400 may include aluminum or a similar material. In an embodiment, at least a portion of the cold plate 400 may be aluminum, and at least a portion of one or more of the inserts 440 and/or the projections 444 may be copper. One or more insert 440 and/or projection 444 may include a material that is more resistant to wear or corrosion by the coolant than a material used for the cold plate 400. For example, the inserts 440 may include tubing to receive the coolant and maintain the coolant separate from surfaces of the cold plate 400. In another example, the projection 444 may include the same material as the insert 440 joined with the projections 444 to provide a fluidly sealed connection through the cold plate.

The inlet 402 and the outlet 404 may use any suitable connection, such as fixed flow controllers. In at least one embodiment, server trays may have fixed flow controllers (such as blind-mate QDs) at determined positions located outside of the cold plate 400 to couple to the cold plate 400, or fluid adapters of the cold plate 400, for coolant flow to the cold plate 400. Such determined positions may not align to provided flow controllers of the cold plate 400. In at least one embodiment, additional flexible tubing may be required. In at least one embodiment, server fluid connection to the cold plate 400 may be made through flexible fixtures (such as a tube) provided outside the server trays and that have a fixed blind-mate connection to the cold plate 400 on one side and that has movable blind-mate connection on another side. In at least one embodiment, as the cold plate 400 incorporates a movable flow controller outside of the server or box 430, there is no need for additional flexible tubing that may introduce additional points of potential failure. In at least one embodiment, a movable blind-mate connection (referred to generally as a flow controller) can be moved horizontally and/or vertically for precise mating with flow controllers on a server's side (such as a server face or a coolant source input and output). In at least one embodiment, movement of a movable flow controller enables support to fit various styles of servers in a rack. In at least one embodiment, sensors and intelligent control may be associated with a flow controller or other part, such as within or on the cold plate 400, to enable monitoring.

The coolant or other fluid may also flow out of a distribution outlet fluid adapter and into a distribution source inlet fluid adapter, transferring fluid with the other components. The distribution fluid adapters may enable receipt and egress of the liquid coolant between the cold plate 400 and one or more other components. The cold plate 400 may use distribution fluid adapters to also serve as a manifold and distribute the flow of cooling fluid to other hardware components of the computer system 450 associated with the cold plate 400, such as a server tray or box 430 which may be removable from a server rack. In an embodiment, the server tray or box 430 may include more than one cold plate 400 to provide cooling and distribute coolant. The cold plate 400 may include any number of fluid adapters in various combinations to transfer cooling fluid.

FIG. 5 illustrates component-level features 500 associated with cold plates for reducing coolant leakage in computer hardware for a data center liquid-cooling system, according to at least one embodiment. The component-level features 500 include a computing or data center device formed of one or more of components 502, 504. In at least one embodiment, component 502 is a board or card, such as a PCB or printed circuit card that is enveloped and shielded to protect components therein. The PCB may hold at least one compute device. The compute device may comprise hardware, such as an ASIC. Other non-limiting examples of the compute device include an IC chip, a CPU, a GPU, a microprocessor, a Field Programmable Gate Array (FPGA), a collection of logic gates or transistors, resistors, capacitors, inductors, diodes, or the like. It should be appreciated that any appropriate type of electrical or optical component or collection of electrical or optical components may be suitable for inclusion in the compute device. Numerous example embodiments will be described below in which a semiconductor package is mounted within a through hole of a PCB. Although PCBs having certain types and form factors appear in the drawings and the discussion, it should be noted that the illustrated and described types and form factors are provided by way of example only. Persons having skill in the art and having reference to this disclosure will readily appreciate that the same or similar apparatus and techniques may also be employed with PCBs having other types and form factors. For example, in some embodiments, the PCB to which the semiconductor package is mounted may comprise an add-in card, such as a PCIe card, which is configured to be coupled to a system board or motherboard of a host system. In other embodiments, the PCB to which the semiconductor package is mounted may be the system board or motherboard of the host system itself. Moreover, the system board or the motherboard may be associated with any type of host system. For example, the PCB may comprise the system board in a multi-node rack-mounted server in a data center, or it may comprise the motherboard of a workstation, desktop, laptop, or mobile device. Other embodiments are also possible.

In at least one embodiment, component 504 is a compute device such as a chip or semiconductor device, such as a CPU, a GPU, or a switch. In at least one embodiment, even though only one component 504 is illustrated, the PCB 502 may have multiple components mounted thereon. In at least one embodiment, the component 504 may include multiple die (such as a multi-core processor device). In at least one embodiment, the cores may be stacked or distributed. In at least one embodiment, the components 502, 504 may have different heat generating features represented by at least locations of the die therein. In the case of the PCB 502, when there are multiple components 504 thereon, each component may be a heat generating feature.

In at least one embodiment, a cold plate 508 to route liquid coolant is associated with the computer device. In the illustration of FIG. 5, the cold plate 508 is associated with the component 504. In at least one embodiment, the cold plate 508 may extend throughout the dimensions of the PCB 502 to provide direct or indirect contact cooling to one or more computing components on the PCB 502. In at least one embodiment, such as when a graphics processing card is the computing device, the cold plate 508 extends over the entire card, but channels 514 in the cold plate 508 may enable concentration of coolant or the flow of coolant over, or to align with, areas of the card having processor or memory-intensive computing devices. The computing device may, therefore, have further computing devices associated therewith.

In at least one embodiment, the cold plate 508 is associated with the computing device 504 via a thermal transfer layer 506. The thermal transfer layer 506 may be a layer having one or more of silicon, a thermal interface material, or air. In at least one embodiment, there may be no thermal transfer layer 506 and the cold plate 508 may be directly associated with the computing device 504. The cold plate 508 may have at least one inlet for coolant inlet line 510 and at least one outlet for coolant outlet line 512. The at least one inlet line 510 may receive a flow of liquid coolant from a source external to the server. The at least one outlet line 512 may provide the flow of coolant to one or more components of the server, or return the flow of liquid coolant to the source external to the server. The cold plate 508 may also include at least one additional outlet line to provide the flow of coolant to external source and may include at least one additional inlet line to receive the flow of coolant from the one or more components of the server. In an embodiment, the inlet line 510 and the outlet line 512 may transfer the flow of coolant with the coolant source outside of the server, such that any connections as potential coolant leakage points are maintained away from the server interior containing the components 502, 504 and/or other devices that are fluid sensitive. A server or computer system may be provided with a single cold plate 508 to provide cooling from a fluid for heat generating devices. For example, the cold plate 508 may be a sole source of cooling from liquid for a computing system, such as for a liquid-cooled server or for a liquid-and air-cooled server.

As illustrated in FIG. 5, a partial cut-through view of the cold plate 508 interior shows the channels 514 able to transfer a flow of coolant, such as between the inlet line 510 to the outlet line 512. The channels 514 may be carved, formed, inlayed, or otherwise provided in the cold plate 508 to form paths adapted to layouts of components 502, 504. The channels 514 may be provided with routes, shapes, angles, sizes, volumes, in parallel, in series, or other aspects based on one or more considerations. The cold plate 508 may include one or more inserts 516 which may control or affect the flow of coolant. In an embodiment, the inserts 516 may include copper. The inserts 516 may include tubing or lining within the cold plate 508 or channels 514 to transfer the flow of coolant to components 502, 504, such as being adapted based on a layout or other considerations. In an embodiment, the inserts 516 may be positioned at one or more areas, such as near the inlet line 510 or the outlet line 512 or other connections, such as to create fluidly sealed connections. The cold plate 508 may also include cooling structures 518, which may include fin structures, microchannels, flow channels, tubing, or other suitable features able to affect the cooling of the cold plate. In an embodiment, the cooling structures 518 may be positioned into a path of coolant flow, such as over, or aligned with, areas of the components 502, 504.

In at least one embodiment, the cold plate 508 may include projections which extend away or out from the cold plate 508, such as towards areas of the components 502, 504. The projections may be a pedestal 520 projecting a fixed distance from the cold plate 508, and/or a bellows 522 able to project a variable distance from the cold plate 508. The projections may be positioned along the channels 514, such as at locations able to provide direct or indirect contact cooling to one or more of the components 502, 504. The projections, such as the pedestal 520 or the bellows 522, may extend from or extend through a surface of the cold plate 508. In an example, the projections may be part of or joined directly to the material of the cold plate 508, such as to extend the surface. In another example, the projections may be part of or joined directly to the material of the inserts 516, such as using one or more joints 526. The projections may be any suitable shape and size, such as a cylinder, rectangular prism, cube, ovoid, cone, or other suitable shapes. The projections may be solid or an enclosed hollow, or may include an opening 524 to allow fluid from the channels 514 to enter the projections toward the components 502, 504, which may improve the cooling. The joints 526 may be part of the inserts 516 and/or the projections, or may be provided separately and connected to the inserts 516 and/or the projections. The joints 526 may extend along a periphery or other feature of the projections to provide a sealed joint for the cold plate 508, such as a tube to form a fluid path from the channels 514 to the projections.

The pedestal 520 may be a fixed extension from the cold plate, able to provide a thermal connection with the components 502, 504. The pedestal 520 may have an opening 524 to allow the flow of coolant from the cold plate 508 to pass into the pedestal 520, such as toward a thermal transfer surface, and then return to the cold plate 508. The bellow 522 may be a collapsible or compressible pedestal 520 or other extension to enable thermal contact with the components 502, 504 of different heights, sizes, or shapes. For example, the bellow 522 may be able to absorb tolerance stack ups for components 502, 504 or other heat generating devices, while at least some of the pedestals 520 may be unable to adjust for variations in different heights of the components 502. The bellow 522 may be able to account for mechanical tolerances of the computing system, including the height differences of the components 502, 504 or other differences, such as by using an accordion-style structure to compress and expand. For example, the cold plate 508 may include a plurality of pedestals 520 and bellows 522 able to receive thermally interface with different components 502, 504 with different heights. Using the bellows 522 to interface at a closer distance with at least some of the components 502, 504 may reduce the amount of thermal material required, the terminal resistance, and the temperature difference. The projections may be brazed, diffusion bonded, welded, soldered, or otherwise joined to the cold plate 508, the joints 526, and/or the inserts 516, or may be provided as a single piece with one or more parts of the cold plate 508. This joining may be able to a leak-free and/or fluidly sealed fluid path. The opening 524 of the projections may be able to receive cooling structures 518 from the channels 514. The cooling structures 518 may also extend from the projection into the channel 514, or may be connected to both the cold plate 508 and the projection. For example, the cooling structures 518 may extend down to, or into, the pedestal 520 or bellow 522 to increase fin area and enable better cooling capacity. In an embodiment, spring-loaded or biased screws, instead of screws without springs or other biasing means, associated with the cold plate 508, such as to secure the cold plate 508, the components 502, 504, or other features, may not be required since the bellows 522 can absorb all tolerances.

In an embodiment, the cold plate 508 may include a top plate and a bottom plate, such as illustrated in FIG. 4A and FIG. 4B. For example, the top plate and bottom plate may be made from aluminum, such as to reduce weight, and may be joined together with brazed or diffusion bonded edges to for a leak-free seal. The liquid paths along the channels 514 may be formed by the sandwich of both the top and bottom plates of the cold plate 508 joined together. The liquid paths can be completely modified to guide liquid flow in any path possible and can be customized as needed. The channels 514 may be adaptable to hotspot cooling at different locations on the system, such as the locations of the components 502, 504, and may be based on other considerations, such as cooling needs and available space. For example, the cold plate 508 may be provided with channels 514 may be adapted to include parallel, series, paths to each of the components 502, 504 or hotspot, or other suitable other paths. A computing system having one or more of the components 502, 504 with location changes may have an existing cold plate having the channels 514 mapped to the previous locations replaced with a new cold plate having the channels 514 adapted to be mapped to the new locations.

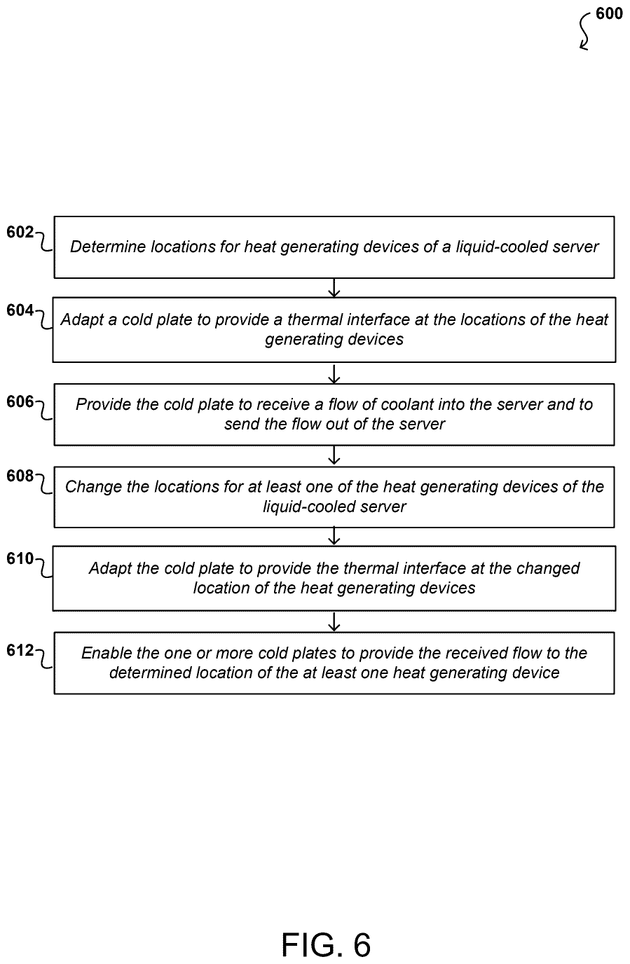

FIG. 6 illustrates an example process 600 that can be performed to use a cold plate adapted to locations of heat generating devices for a liquid-cooled server, according to at least one embodiment. It should be understood that for this and other processes presented herein that there may be additional, fewer, or alternative steps performed or similar or alternative orders, or at least partially in parallel, within the scope of the various embodiments unless otherwise specifically stated. Further, although this and other examples herein will be discussed with respect to coolant flow and thermal properties for servers and related components, there can be other types of parameters and measurements determined for other types of cooling systems or devices as well, within the scope of various embodiments. In this example, locations are determined 602 for heat generating devices of a liquid-cooled server. The liquid-cooled server may be a server tray or box having one or more circuit boards, and may be located in a rack able to receive a plurality of servers. The liquid-cooled server may include a plurality of heat generating devices or components having a heat generating feature, such as processing units, storage drives, compute devices, sensors, cards, circuit boards, memory, hubs, controllers, interfaces, networking devices, circuits, or other components.

A cold plate is adapted 604 to provide thermal interfaces at the locations of the one or more heat generating devices. The thermal interfaces may provide at least a portion of the received flow closer to the corresponding heat generating devices. The cold plate may provide hotspot cooling at a plurality of locations of the heat generating devices. The liquid-cooled server may include pedestals extending from the cold plate at the thermal interfaces to receive the heat generating devices. The pedestals may include compressible bellows to account for mechanical tolerances and/or adjust to different chip heights. The cold plate may include one or more channels adaptable according to the positions of the heat generating devices. The channels may include one or more inserts on at least an interior surface of the cold plate to affect the flow of liquid coolant. The inserts can include microchannels or fins positioned within the cold plate at the locations of the one or more heat generating devices.

The cold plate is provided 606 to receive a flow of coolant into the server and to send the flow out of the server. The cold plate may be able to fluidly connect with the external liquid coolant source outside of the server, such as using any of at least an interface, a coolant loop, inlets and outlets, and a plurality of connectors and hoses. The cold plate may have one or more surfaces that the heat generating devices can be positioned on. One or more cold plates may be fluidly connected together, such as in a daisy-chain configuration. The flow of coolant may be provided to server through the cold plate from an external liquid coolant source. An interface may be used between the cold plates and the external liquid coolant source. The interface may be part of the liquid-cooled server. More than one external liquid coolant source may provide flows of coolant to the cold plate. The cold plate may be able to connect to the flow of liquid coolant using a manual connection or a blind-mate connection.

The locations are changed 608 for at least one of the heat generating devices of the liquid-cooled server. The locations of the heat generating devices may be changed for an existing liquid-cooled server or for a new liquid-cooled server. The cold plate is adapted 610 to provide the thermal interface at the changed location of the one or more heat generating devices. The channels may include one or more features or inserts that are changed to provide the thermal interface at the changed location of the one or more heat generating devices. A cold plate may be provided new channels to provide the thermal interface at the changed location of the one or more heat generating devices. The one or more cold plates are enabled 612 to provide the received flow to the determined location of the heat generating devices. The cold plate may include paths fluidly sealed within the at least one cold plate to provide the received flow to the thermal interface. A source of cooling from liquid for the server is only provided from the at least one cold plate. The one or more cold plates may be enabled to provide a source of cooling to the heat generating devices. The components may be positioned on one or more surfaces of the cold plates to receive the source of cooling, where the surfaces are cooled by the flow of coolant in contact with the surfaces. The one or more cold plates may be enabled to further provide the flow of coolant to the at least one additional component. The component may be in fluid communication with the cold plates. The components may provide the flow of coolant back to the cold plates. The cold plates may provide the flow of coolant back to the external liquid coolant source.

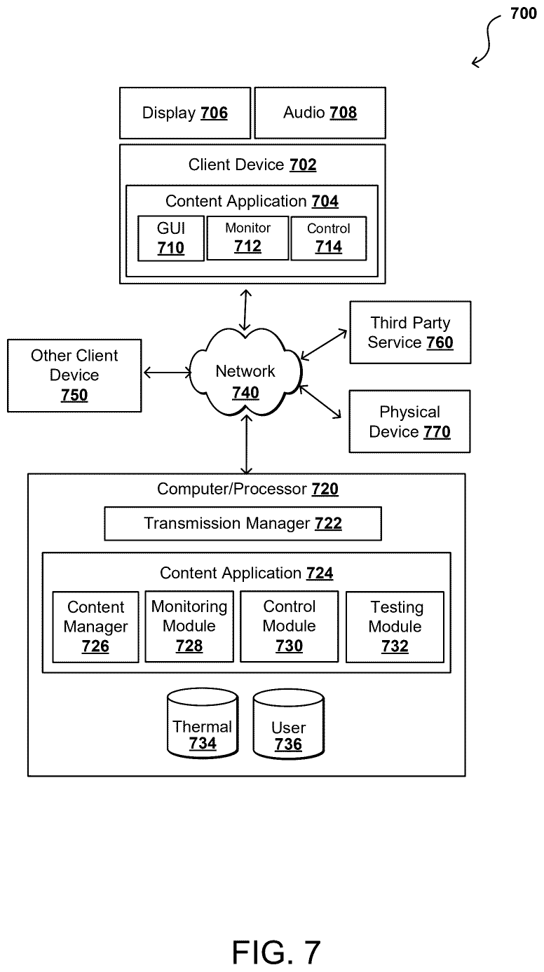

FIG. 7 illustrates an example network configuration 700 of components that can be used to implement aspects of various embodiments, such as to provide, generate, modify, encode, process, fuse, and/or transmit liquid coolant data or server thermal data, calculated measurements, or other such content. In at least one embodiment, a client device 702 can generate or receive data for a session using components of a content application 704 on the client device 702 and data stored locally on that client device. In at least one embodiment, a content application 724 executing on a computer or processor 720 (e.g., a cloud server or control system) may initiate a session associated with at least one client device 702 (e.g., a vehicle or robot), as may use a session manager and user data stored in a user database 736, and can cause content such as liquid coolant data or server thermal data to be selected and/or retrieved from a repository 734 to be used by a testing module 732 to calculate one or more performance metrics for a monitoring module 728, which can provide flow data or thermal data to a control module 730 to control a flow or temperature, in an environment where the data is to be used to determine appropriate operation. A content manager 726 may work with at these various modules to perform testing and analysis, and potentially instruct any actions to be taken in response to a performance metric failing to satisfy an operational requirements. At least a portion of this data or instructional content can be transmitted to the client device 702 and/or a physical device 770 using an appropriate transmission manager 722 to send by download, streaming, or another such transmission channel. An encoder may be used to encode and/or compress at least some of this data before transmitting to the client device 702. In at least one embodiment, the client device 702 receiving such content can provide this content to a corresponding content application 704, which may also or alternatively include a graphical user interface 710, a flow monitor module 712, and a control module 714 for use in providing, synthesizing, rendering, compositing, modifying, or using content for presentation, navigation, control, (or other purposes) on or by the client device 702, such as may be transmitted to the physical device 770. In some embodiments, the computer/processor 720 and client device 702 may be able to communicate directly without needing to transmit data over a network 740, in order to avoid issues with latency and availability, etc.. A decoder may also be used to decode data received over the network 740 for presentation via client device 702, such as imaging content or performance metrics through a display device 706 and audio, such as corresponding sounds or synthesized speech, through at least one audio playback device 708, such as speakers or headphones. In at least one embodiment, at least some of this content may already be stored on, rendered on, or accessible to client device 702 such that transmission over a network 740 is not required for at least that portion of content, such as where that content (e.g., thermal data) may have been previously downloaded or stored locally on a hard drive or optical disk. In at least one embodiment, a transmission mechanism such as data streaming can be used to transfer this content from the computer/processor 720, or user database 736, to the client device 702. In at least one embodiment, at least a portion of this content can be obtained, enhanced, and/or streamed from another source, such as a third party service 760 or other client device 750, that may also include a content application for generating, updating, enhancing, or providing map content. In at least one embodiment, portions of this functionality can be performed using multiple computing devices, or multiple processors within one or more computing devices, such as may include a combination of CPUs and GPUs (Graphics Processing Unit).

In at least some of these examples, client devices can include any appropriate computing devices, as may include a desktop computer, notebook computer, set-top box, streaming device, gaming console, smartphone, tablet computer, VR headset, AR goggles, wearable computer, or a smart television. Each client device can submit a request across at least one wired or wireless network, as may include the Internet, an Ethernet, a local area network (LAN), or a cellular network, among other such options. In this example, these requests can be submitted to an address associated with a cloud provider, who may operate or control one or more electronic resources in a cloud provider environment, such as may include a data center or server farm. In at least one embodiment, the request may be received or processed by at least one edge server, that sits on a network edge and is outside at least one security layer associated with the cloud provider environment. In this way, latency can be reduced by allowing the client devices to interact with servers that are in closer proximity, while also improving security of resources in the cloud provider environment.

In at least one embodiment, such a system can be used for monitoring or managing thermal conditions of a server which includes cold plates for reducing or eliminating coolant leaks in computer hardware. In other embodiments, such a system can be used for other purposes, such as for providing control of liquid coolant flow, or for performing deep learning operations. In at least one embodiment, such a system can be implemented using an edge device or may incorporate one or more Virtual Machines (VMs). In at least one embodiment, such a system can be implemented at least partially in a data center or at least partially using cloud computing resources.

### Data Center

Data centers may use air cooling to cool servers to prevent malfunction due to high heat. Air cooling of high density servers has become inefficient and ineffective in view of high heat requirements caused by present day computing devices. Often, air cooling is insufficient to properly cool computing devices in present day data centers. In at least one embodiment, to remedy this some servers use liquid-cooling to cool high-power components such as CPUs, GPUs, other processing units, or the like. In at least one embodiment, cold plates that receive a liquid coolant are coupled to high-power components. In at least one embodiment, cold plates can transfer heat energy from a component to a flowing liquid coolant. In at least one embodiment, liquid coolant is flowed from a cold plate to a distribution unit (e.g., a coolant distribution unit (CDU), etc.) where heat is rejected from coolant. In at least one embodiment, cooled liquid coolant is then flowed back to cold plates to remove more heat from server components. Although high-power components can be cooled with liquid coolant via cold plates, low-power components are still cooled via air cooling. Cooling low-power components with air requires energy to run fans to move air through servers. Air has a relatively low heat capacity, so a large amount of air is moved over server components to provide proper cooling. Although cooling efficiency may be increased by cooling high-power server components via liquid-cooling in data centers, cooling low-power server components via air cooling hampers cooling efficiency in data centers.

Some data centers cool servers (e.g., server components) via liquid immersion cooling. In some data centers, entire server units are submerged in a vat (e.g., a tank, a tub, a pool, etc.) of dielectric liquid coolant. Heat from server components (e.g., both high-power server components and low-power server components) is transferred to dielectric liquid coolant. Often, dielectric liquid coolant has a greater heat capacity than air, meaning that server components are more effectively cooled than by air cooling. However, dielectric liquid coolant may have a lower heat capacity than other liquid coolants, such as water, that may be used for cold plate cooling as described above. Thus, high-power server components may not be efficiently and/or effectively cooled by immersion cooling.

In at least one embodiment, a cooling system for a data center has dual-cooling modes. In at least one embodiment, a data center cooling system includes one or more first cooling loops that flow a first coolant to cool high-power server components via cold plates and one or more second cooling loops that flow a second coolant to cool low-power server components via immersion cooling. In at least one embodiment, a data center server receives a first coolant from a first CDU. First coolant may be routed through piping, tubing, and/or one or more manifolds along one or more first flow paths between a first CDU and one or more servers. In at least one embodiment, one or more servers are disposed in a data center rack (e.g., supported in a rack of a data center). First coolant may flow into a server chassis through a first inlet. In at least one embodiment, first coolant is flowed through one or more cold plates coupled to one or more high-power components such as a CPU, GPU, etc. within a server chassis. First coolant may receive heat from one or more high-power components and flow out of a server chassis through a first outlet. Once out of a server chassis, first coolant may flow through piping, tubing, and/or one or more manifolds along one or more first flow paths to a first CDU where first coolant is cooled then returned back to one or more servers along one or more first flow paths. In at least one embodiment, a first CDU may cause heat to be exchanged between first coolant and another coolant such as water. Another coolant may be flowed from a first CDU to a cooling tower, chiller, dry cooler, etc. where heat from first coolant is rejected to an ambient environment. In at least one embodiment, a first flow path is a loop along which first coolant flows.

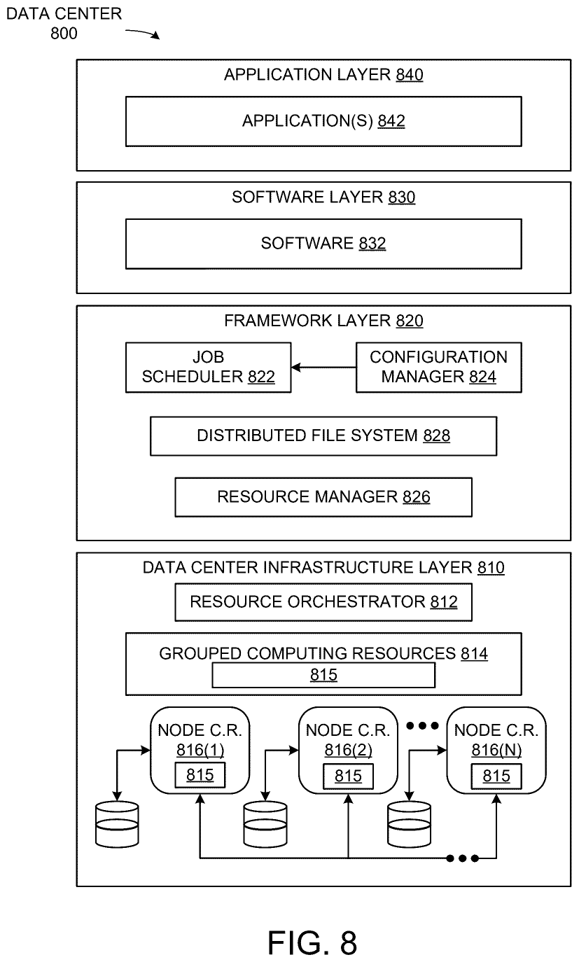

FIG. 8 illustrates an example data center 800, in which at least one embodiment may be used. In at least one embodiment, data center 800 includes a data center infrastructure layer 810, a framework layer 820, a software layer 830 and an application layer 840.

In at least one embodiment, as shown in FIG. 8, data center infrastructure layer 810 may include a resource orchestrator 812, grouped computing resources 814, and node computing resources (“node C.R.s”) 816(1)-816(N), where “N” represents a positive integer (which may be a different integer “N” than used in other figures). In at least one embodiment, node C.R.s 816(1)-816(N) may include, but are not limited to, any number of central processing units (“CPUs”) or other processors (including accelerators, field programmable gate arrays (FPGAs), graphics processors, etc.), memory storage devices 818(1)-818(N) (e.g., dynamic read-only memory, solid state storage or disk drives), network input/output (“NW I/O”) devices, network switches, virtual machines (“VMs”), power modules, and cooling modules, etc. In at least one embodiment, one or more node C.R.s from among node C.R.s 816(1)-816(N) may be a server having one or more of above-mentioned computing resources.

In at least one embodiment, grouped computing resources 814 may include separate groupings of node C.R.s housed within one or more racks (not shown), or many racks housed in data centers at various geographical locations (also not shown). In at least one embodiment, separate groupings of node C.R.s within grouped computing resources 814 may include grouped compute, network, memory or storage resources that may be configured or allocated to support one or more workloads. In at least one embodiment, several node C.R.s including CPUs or processors may grouped within one or more racks to provide compute resources to support one or more workloads. In at least one embodiment, one or more racks may also include any number of power modules, cooling modules, and network switches, in any combination.

In at least one embodiment, resource orchestrator 812 may configure or otherwise control one or more node C.R.s 816(1)-816(N) and/or grouped computing resources 814. In at least one embodiment, resource orchestrator 812 may include a software design infrastructure (“SDI”) management entity for data center 800. In at least one embodiment, resource orchestrator 812 may include hardware, software or some combination thereof.

In at least one embodiment, as shown in FIG. 8, framework layer 820 includes a job scheduler 822, a configuration manager 824, a resource manager 826 and a distributed file system 828. In at least one embodiment, framework layer 820 may include a framework to support software 832 of software layer 830 and/or one or more application(s) 842 of application layer 840. In at least one embodiment, software 832 or application(s) 842 may respectively include web-based service software or applications, such as those provided by Amazon Web Services, Google Cloud and Microsoft Azure. In at least one embodiment, framework layer 820 may be, but is not limited to, a type of free and open-source software web application framework such as Apache Spark™ (hereinafter “Spark”) that may use distributed file system 828 for large-scale data processing (e.g., “big data”). In at least one embodiment, job scheduler 822 may include a Spark driver to facilitate scheduling of workloads supported by various layers of data center 800. In at least one embodiment, configuration manager 824 may be capable of configuring different layers such as software layer 830 and framework layer 820 including Spark and distributed file system 828 for supporting large-scale data processing. In at least one embodiment, resource manager 826 may be capable of managing clustered or grouped computing resources mapped to or allocated for support of distributed file system 828 and job scheduler 822. In at least one embodiment, clustered or grouped computing resources may include grouped computing resources 814 at data center infrastructure layer 810. In at least one embodiment, resource manager 826 may coordinate with resource orchestrator 812 to manage these mapped or allocated computing resources.

In at least one embodiment, software 832 included in software layer 830 may include software used by at least portions of node C.R.s 816(1)-816(N), grouped computing resources 814, and/or distributed file system 828 of framework layer 820. In at least one embodiment, one or more types of software may include, but are not limited to, Internet web page search software, e-mail virus scan software, database software, and streaming video content software.

In at least one embodiment, application(s) 842 included in application layer 840 may include one or more types of applications used by at least portions of node C.R.s 816(1)-816(N), grouped computing resources 814, and/or distributed file system 828 of framework layer 820. In at least one embodiment, one or more types of applications may include, but are not limited to, any number of a genomics application, a cognitive compute, application and a machine learning application, including training or inferencing software, machine learning framework software (e.g., PyTorch, TensorFlow, Caffe, etc.) or other machine learning applications used in conjunction with one or more embodiments.

In at least one embodiment, any of configuration manager 824, resource manager 826, and resource orchestrator 812 may implement any number and type of self-modifying actions based on any amount and type of data acquired in any technically feasible fashion. In at least one embodiment, self-modifying actions may relieve a data center operator of data center 800 from making possibly bad configuration decisions and possibly avoiding underused and/or poor performing portions of a data center.

In at least one embodiment, data center 800 may include tools, services, software or other resources to train one or more machine learning models or predict or infer information using one or more machine learning models according to one or more embodiments described herein. For example, in at least one embodiment, a machine learning model may be trained by calculating weight parameters according to a neural network architecture using software and computing resources described above with respect to data center 800. In at least one embodiment, trained machine learning models corresponding to one or more neural networks may be used to infer or predict information using resources described above with respect to data center 800 by using weight parameters calculated through one or more training techniques described herein.

In at least one embodiment, data center may use CPUs, application-specific integrated circuits (ASICs), GPUs, FPGAs, or other hardware to perform training and/or inferencing using above-described resources. Moreover, one or more software and/or hardware resources described above may be configured as a service to allow users to train or performing inferencing of information, such as image recognition, speech recognition, or other artificial intelligence services.

Inference and/or training logic 815 are used to perform inferencing and/or training operations associated with one or more embodiments. In at least one embodiment, inference and/or training logic 815 may be used in system FIG. 8 for inferencing or predicting operations based, at least in part, on weight parameters calculated using neural network training operations, neural network functions and/or architectures, or neural network use cases described herein.

Embodiments presented herein include cold plates in computer hardware.

### Servers and Data Centers

The following figures set forth, without limitation, exemplary network server and data center based systems that can be used to implement at least one embodiment.

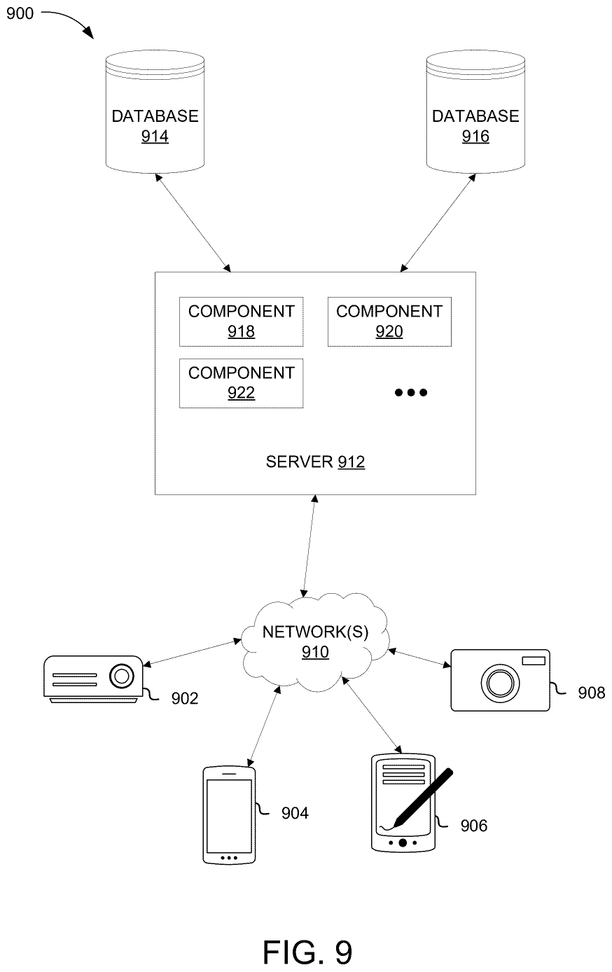

FIG. 9 illustrates a distributed system 900, in accordance with at least one embodiment. In at least one embodiment, distributed system 900 includes one or more client computing devices 902, 904, 906, and 908, which are configured to execute and operate a client application such as a web browser, proprietary client, and/or variations thereof over one or more network(s) 910. In at least one embodiment, server 912 may be communicatively coupled with remote client computing devices 902, 904, 906, and 908 via network 910.

In at least one embodiment, server 912 may be adapted to run one or more services or software applications such as services and applications that may manage session activity of single sign-on (SSO) access across multiple data centers. In at least one embodiment, server 912 may also provide other services or software applications can include non-virtual and virtual environments. In at least one embodiment, these services may be offered as web-based or cloud services or under a Software as a Service (SaaS) model to users of client computing devices 902, 904, 906, and/or 908. In at least one embodiment, users operating client computing devices 902, 904, 906, and/or 908 may in turn utilize one or more client applications to interact with server 912 to utilize services provided by these components.

In at least one embodiment, software components 918, 920, and 922 of distributed system 900 are implemented on server 912. In at least one embodiment, one or more components of distributed system 900 and/or services provided by these components may also be implemented by one or more of client computing devices 902, 904, 906, and/or 908. In at least one embodiment, users operating client computing devices may then utilize one or more client applications to use services provided by these components. In at least one embodiment, these components may be implemented in hardware, firmware, software, or combinations thereof. It should be appreciated that various different system configurations are possible, which may be different from distributed system 900. The embodiment shown in FIG. 9 is thus one example of a distributed system for implementing an embodiment system and is not intended to be limiting.

In at least one embodiment, client computing devices 902, 904, 906, and/or 908 may include various types of computing systems. In at least one embodiment, a client computing device may include portable handheld devices (e.g., an iPhone®, cellular telephone, an iPad®, computing tablet, a personal digital assistant (PDA)) or wearable devices (e.g., a Google Glass® head mounted display), running software such as Microsoft Windows Mobile®, and/or a variety of mobile operating systems such as iOS, Windows Phone, Android, BlackBerry 10, Palm OS, and/or variations thereof. In at least one embodiment, devices may support various applications such as various Internet-related apps, e-mail, short message service (SMS) applications, and may use various other communication protocols. In at least one embodiment, client computing devices may also include general purpose personal computers including, by way of example, personal computers and/or laptop computers running various versions of Microsoft Windows®, Apple Macintosh®, and/or Linux operating systems. In at least one embodiment, client computing devices can be workstation computers running any of a variety of commercially-available UNIX® or UNIX-like operating systems, including without limitation a variety of GNU/Linux operating systems, such as Google Chrome OS. In at least one embodiment, client computing devices may also include electronic devices such as a thin-client computer, an Internet-enabled gaming system (e.g., a Microsoft Xbox gaming console with or without a Kinect® gesture input device), and/or a personal messaging device, capable of communicating over network(s) 910. Although distributed system 900 in FIG. 9 is shown with four client computing devices, any number of client computing devices may be supported. Other devices, such as devices with sensors, etc., may interact with server 912.

In at least one embodiment, network(s) 910 in distributed system 900 may be any type of network that can support data communications using any of a variety of available protocols, including without limitation TCP/IP (transmission control protocol/Internet protocol), SNA (systems network architecture), IPX (Internet packet exchange), AppleTalk, and/or variations thereof. In at least one embodiment, network(s) 910 can be a local area network (LAN), networks based on Ethernet, Token-Ring, a wide-area network, Internet, a virtual network, a virtual private network (VPN), an intranet, an extranet, a public switched telephone network (PSTN), an infra-red network, a wireless network (e.g., a network operating under any of the Institute of Electrical and Electronics (IEEE) 802.11 suite of protocols, Bluetooth®, and/or any other wireless protocol), and/or any combination of these and/or other networks.

In at least one embodiment, server 912 may be composed of one or more general purpose computers, specialized server computers (including, by way of example, PC (personal computer) servers, UNIX® servers, mid-range servers, mainframe computers, rack-mounted servers, etc.), server farms, server clusters, or any other appropriate arrangement and/or combination. In at least one embodiment, server 912 can include one or more virtual machines running virtual operating systems, or other computing architectures involving virtualization. In at least one embodiment, one or more flexible pools of logical storage devices can be virtualized to maintain virtual storage devices for a server. In at least one embodiment, virtual networks can be controlled by server 912 using software defined networking. In at least one embodiment, server 912 may be adapted to run one or more services or software applications.

In at least one embodiment, server 912 may run any operating system, as well as any commercially available server operating system. In at least one embodiment, server 912 may also run any of a variety of additional server applications and/or mid-tier applications, including HTTP (hypertext transport protocol) servers, FTP (file transfer protocol) servers, CGI (common gateway interface) servers, JAVA® servers, database servers, and/or variations thereof. In at least one embodiment, exemplary database servers include without limitation those commercially available from Oracle, Microsoft, Sybase, IBM (International Business Machines), and/or variations thereof.

In at least one embodiment, server 912 may include one or more applications to analyze and consolidate data feeds and/or event updates received from users of client computing devices 902, 904, 906, and 908. In at least one embodiment, data feeds and/or event updates may include, but are not limited to, Twitter® feeds, Facebook® updates or real-time updates received from one or more third party information sources and continuous data streams, which may include real-time events related to sensor data applications, financial tickers, network performance measuring tools (e.g., network monitoring and traffic management applications), clickstream analysis tools, automobile traffic monitoring, and/or variations thereof. In at least one embodiment, server 912 may also include one or more applications to display data feeds and/or real-time events via one or more display devices of client computing devices 902, 904, 906, and 908.

In at least one embodiment, distributed system 900 may also include one or more databases 914 and 916. In at least one embodiment, databases may provide a mechanism for storing information such as user interactions information, usage patterns information, adaptation rules information, and other information. In at least one embodiment, databases 914 and 916 may reside in a variety of locations. In at least one embodiment, one or more of databases 914 and 916 may reside on a non-transitory storage medium local to (and/or resident in) server 912. In at least one embodiment, databases 914 and 916 may be remote from server 912 and in communication with server 912 via a network-based or dedicated connection. In at least one embodiment, databases 914 and 916 may reside in a storage-area network (SAN). In at least one embodiment, any necessary files for performing functions attributed to server 912 may be stored locally on server 912 and/or remotely, as appropriate. In at least one embodiment, databases 914 and 916 may include relational databases, such as databases that are adapted to store, update, and retrieve data in response to SQL-formatted commands.

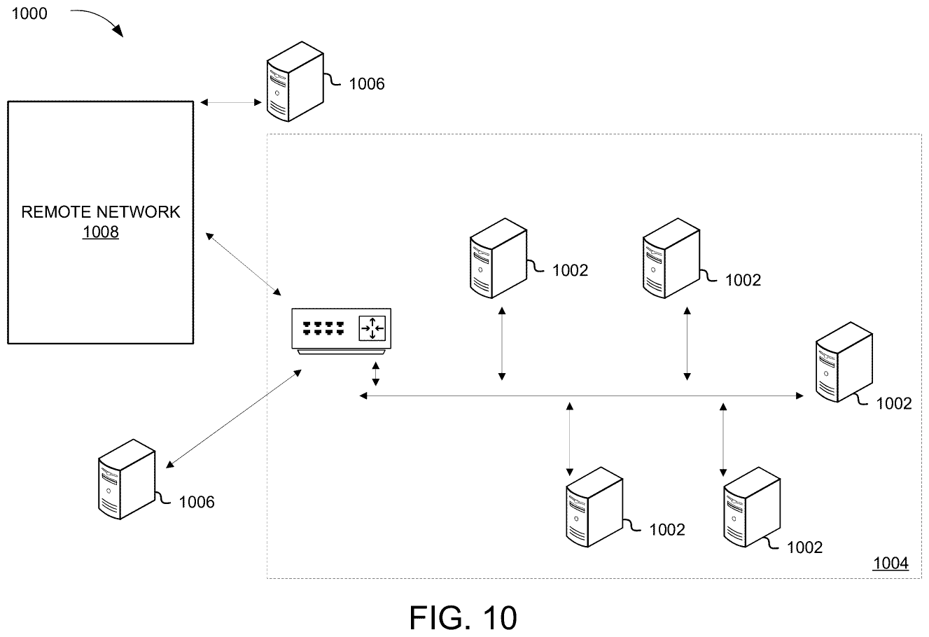

FIG. 10 illustrates a system 1000 that includes a client-server network 1004 formed by a plurality of network server computers 1002 which are interlinked, in accordance with at least one embodiment. In at least one embodiment, each network server computer 1002 stores data accessible to other network server computers 1002 and to client computers 1006 and networks 1008 which link into a wide area network 1004. In at least one embodiment, configuration of a client-server network 1004 may change over time as client computers 1006 and one or more networks 1008 connect and disconnect from a network 1004, and as one or more trunk line server computers 1002 are added or removed from a network 1004. In at least one embodiment, when a client computer 1006 and a network 1008 are connected with network server computers 1002, client-server network includes such client computer 1006 and network 1008. In at least one embodiment, the term computer includes any device or machine capable of accepting data, applying prescribed processes to data, and supplying results of processes.

In at least one embodiment, client-server network 1004 stores information which is accessible to network server computers 1002, remote networks 1008 and client computers 1006. In at least one embodiment, network server computers 1002 are formed by main frame computers minicomputers, and/or microcomputers having one or more processors each. In at least one embodiment, server computers 1002 are linked together by wired and/or wireless transfer media, such as conductive wire, fiber optic cable, and/or microwave transmission media, satellite transmission media or other conductive, optic or electromagnetic wave transmission media. In at least one embodiment, client computers 1006 access a network server computer 1002 by a similar wired or a wireless transfer medium. In at least one embodiment, a client computer 1006 may link into a client-server network 1004 using a modem and a standard telephone communication network. In at least one embodiment, alternative carrier systems such as cable and satellite communication systems also may be used to link into client-server network 1004. In at least one embodiment, other private or time-shared carrier systems may be used. In at least one embodiment, network 1004 is a global information network, such as the Internet. In at least one embodiment, network is a private intranet using similar protocols as the Internet, but with added security measures and restricted access controls. In at least one embodiment, network 1004 is a private, or semi-private network using proprietary communication protocols.

In at least one embodiment, client computer 1006 is any end user computer, and may also be a mainframe computer, mini-computer or microcomputer having one or more microprocessors. In at least one embodiment, server computer 1002 may at times function as a client computer accessing another server computer 1002. In at least one embodiment, remote network 1008 may be a local area network, a network added into a wide area network through an independent service provider (ISP) for the Internet, or another group of computers interconnected by wired or wireless transfer media having a configuration which is either fixed or changing over time. In at least one embodiment, client computers 1006 may link into and access a network 1004 independently or through a remote network 1008.

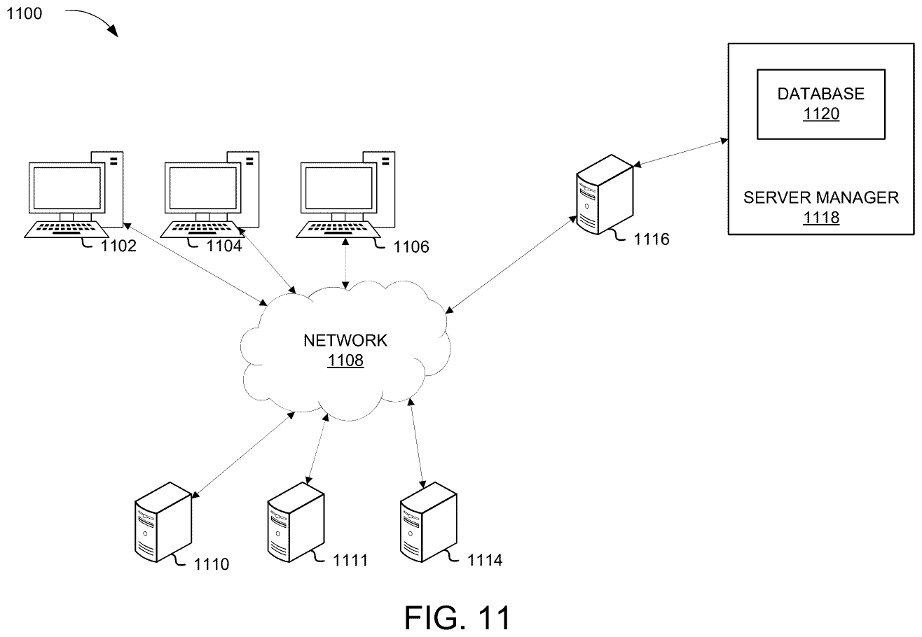

FIG. 11 illustrates a computer network 1100 connecting one or more computing machines, in accordance with at least one embodiment. In at least one embodiment, network 1108 may be any type of electronically connected group of computers including, for instance, the following networks: Internet, Intranet, Local Area Networks (LAN), Wide Area Networks (WAN) or an interconnected combination of these network types. In at least one embodiment, connectivity within a network 1108 may be a remote modem, Ethernet (IEEE 802.3), Token Ring (IEEE 802.5), Fiber Distributed Datalink Interface (FDDI), Asynchronous Transfer Mode (ATM), or any other communication protocol. In at least one embodiment, computing devices linked to a network may be desktop, server, portable, handheld, set-top box, personal digital assistant (PDA), a terminal, or any other desired type or configuration. In at least one embodiment, depending on their functionality, network connected devices may vary widely in processing power, internal memory, and other performance aspects. In at least one embodiment, communications within a network and to or from computing devices connected to a network may be either wired or wireless. In at least one embodiment, network 1108 may include, at least in part, the world-wide public Internet which generally connects a plurality of users in accordance with a client-server model in accordance with a transmission control protocol/internet protocol (TCP/IP) specification. In at least one embodiment, client-server network is a dominant model for communicating between two computers. In at least one embodiment, a client computer (“client”) issues one or more commands to a server computer (“server”). In at least one embodiment, server fulfills client commands by accessing available network resources and returning information to a client pursuant to client commands. In at least one embodiment, client computer systems and network resources resident on network servers are assigned a network address for identification during communications between elements of a network. In at least one embodiment, communications from other network connected systems to servers will include a network address of a relevant server/network resource as part of communication so that an appropriate destination of a data/request is identified as a recipient. In at least one embodiment, when a network 1108 comprises the global Internet, a network address is an IP address in a TCP/IP format which may, at least in part, route data to an e-mail account, a website, or other Internet tool resident on a server. In at least one embodiment, information and services which are resident on network servers may be available to a web browser of a client computer through a domain name (e.g., www. site. com) which maps to an IP address of a network server.

In at least one embodiment, a plurality of clients 1102, 1104, and 1106 are connected to a network 1108 via respective communication links. In at least one embodiment, each of these clients may access a network 1108 via any desired form of communication, such as via a dial-up modem connection, cable link, a digital subscriber line (DSL), wireless or satellite link, or any other form of communication. In at least one embodiment, each client may communicate using any machine that is compatible with a network 1108, such as a personal computer (PC), work station, dedicated terminal, personal data assistant (PDA), or other similar equipment. In at least one embodiment, clients 1102, 1104, and 1106 may or may not be located in a same geographical area.

In at least one embodiment, a plurality of servers 1110, 1112, and 1114 are connected to a network 1108 to serve clients that are in communication with a network 1108. In at least one embodiment, each server is typically a powerful computer or device that manages network resources and responds to client commands. In at least one embodiment, servers include computer readable data storage media such as hard disk drives and RAM memory that store program instructions and data. In at least one embodiment, servers 1110, 1112, 1114 run application programs that respond to client commands. In at least one embodiment, server 1110 may run a web server application for responding to client requests for HTML pages and may also run a mail server application for receiving and routing electronic mail. In at least one embodiment, other application programs, such as an FTP server or a media server for streaming audio/video data to clients may also be running on a server 1110. In at least one embodiment, different servers may be dedicated to performing different tasks. In at least one embodiment, server 1110 may be a dedicated web server that manages resources relating to web sites for various users, whereas a server 1112 may be dedicated to provide electronic mail (email) management. In at least one embodiment, other servers may be dedicated for media (audio, video, etc.), file transfer protocol (FTP), or a combination of any two or more services that are typically available or provided over a network. In at least one embodiment, each server may be in a location that is the same as or different from that of other servers. In at least one embodiment, there may be multiple servers that perform mirrored tasks for users, thereby relieving congestion or minimizing traffic directed to and from a single server. In at least one embodiment, servers 1110, 1112, 1114 are under control of a web hosting provider in a business of maintaining and delivering third party content over a network 1108.

In at least one embodiment, web hosting providers deliver services to two different types of clients. In at least one embodiment, one type, which may be referred to as a browser, requests content from servers 1110, 1112, 1114 such as web pages, email messages, video clips, etc. In at least one embodiment, a second type, which may be referred to as a user, hires a web hosting provider to maintain a network resource such as a web site, and to make it available to browsers. In at least one embodiment, users contract with a web hosting provider to make memory space, processor capacity, and communication bandwidth available for their desired network resource in accordance with an amount of server resources a user desires to utilize.

In at least one embodiment, in order for a web hosting provider to provide services for both of these clients, application programs which manage a network resources hosted by servers must be properly configured. In at least one embodiment, program configuration process involves defining a set of parameters which control, at least in part, an application program's response to browser requests and which also define, at least in part, a server resources available to a particular user.

In one embodiment, an intranet server 1116 is in communication with a network 1108 via a communication link. In at least one embodiment, intranet server 1116 is in communication with a server manager 1118. In at least one embodiment, server manager 1118 comprises a database of an application program configuration parameters which are being utilized in servers 1110, 1112, 1114. In at least one embodiment, users modify a database 1120 via an intranet server 1116, and a server manager 1118 interacts with servers 1110, 1112, 1114 to modify application program parameters so that they match a content of a database. In at least one embodiment, a user logs onto an intranet server 1116 by connecting to an intranet server 1116 via client 1102 and entering authentication information, such as a username and password.

In at least one embodiment, when a user wishes to sign up for new service or modify an existing service, an intranet server 1116 authenticates a user and provides a user with an interactive screen display/control panel that allows a user to access configuration parameters for a particular application program. In at least one embodiment, a user is presented with a number of modifiable text boxes that describe aspects of a configuration of a user's web site or other network resource. In at least one embodiment, if a user desires to increase memory space reserved on a server for its web site, a user is provided with a field in which a user specifies a desired memory space. In at least one embodiment, in response to receiving this information, an intranet server 1116 updates a database 1120. In at least one embodiment, server manager 1118 forwards this information to an appropriate server, and a new parameter is used during application program operation. In at least one embodiment, an intranet server 1116 is configured to provide users with access to configuration parameters of hosted network resources (e.g., web pages, email, FTP sites, media sites, etc.), for which a user has contracted with a web hosting service provider.

### Cloud Computing and Services

The following figures set forth, without limitation, exemplary cloud-based systems that can be used to implement at least one embodiment.

In at least one embodiment, cloud computing is a style of computing in which dynamically scalable and often virtualized resources are provided as a service over the Internet. In at least one embodiment, users need not have knowledge of, expertise in, or control over technology infrastructure, which can be referred to as “in the cloud,” that supports them. In at least one embodiment, cloud computing incorporates infrastructure as a service, platform as a service, software as a service, and other variations that have a common theme of reliance on the Internet for satisfying computing needs of users. In at least one embodiment, a typical cloud deployment, such as in a private cloud (e.g., enterprise network), or a data center (DC) in a public cloud (e.g., Internet) can consist of thousands of servers (or alternatively, VMs), hundreds of Ethernet, Fiber Channel or Fiber Channel over Ethernet (FCOE) ports, switching and storage infrastructure, etc. In at least one embodiment, cloud can also consist of network services infrastructure like IPsec VPN hubs, firewalls, load balancers, wide area network (WAN) optimizers etc. In at least one embodiment, remote subscribers can access cloud applications and services securely by connecting via a VPN tunnel, such as an IPsec VPN tunnel.

In at least one embodiment, cloud computing is a model for enabling convenient, on-demand network access to a shared pool of configurable computing resources (e.g., networks, servers, storage, applications, and services) that can be rapidly provisioned and released with minimal management effort or service provider interaction.

In at least one embodiment, cloud computing is characterized by on-demand self-service, in which a consumer can unilaterally provision computing capabilities, such as server time and network storage, as needed automatically without requiring human inter-action with each service's provider. In at least one embodiment, cloud computing is characterized by broad network access, in which capabilities are available over a network and accessed through standard mechanisms that promote use by heterogeneous thin or thick client platforms (e.g., mobile phones, laptops, and PDAs). In at least one embodiment, cloud computing is characterized by resource pooling, in which a provider's computing resources are pooled to serve multiple consumers using a multi-tenant model, with different physical and virtual resources dynamically as-signed and reassigned according to consumer demand. In at least one embodiment, there is a sense of location independence in that a customer generally has no control or knowledge over an exact location of provided resources, but may be able to specify location at a higher level of abstraction (e.g., country, state, or data center). In at least one embodiment, examples of resources include storage, processing, memory, network bandwidth, and virtual machines. In at least one embodiment, cloud computing is characterized by rapid elasticity, in which capabilities can be rapidly and elastically provisioned, in some cases automatically, to quickly scale out and rapidly released to quickly scale in. In at least one embodiment, to a consumer, capabilities available for provisioning often appear to be unlimited and can be purchased in any quantity at any time. In at least one embodiment, cloud computing is characterized by measured service, in which cloud systems automatically control and optimize resource use by leveraging a metering capability at some level of abstraction appropriate to a type of service (e.g., storage, processing, bandwidth, and active user accounts). In at least one embodiment, resource usage can be monitored, controlled, and reported providing transparency for both a provider and consumer of a utilized service.

In at least one embodiment, cloud computing may be associated with various services. In at least one embodiment, cloud Software as a Service (SaaS) may refer to as service in which a capability provided to a consumer is to use a provider's applications running on a cloud infrastructure. In at least one embodiment, applications are accessible from various client devices through a thin client interface such as a web browser (e.g., web-based email). In at least one embodiment, consumer does not manage or control underlying cloud infrastructure including network, servers, operating systems, storage, or even individual application capabilities, with a possible exception of limited user-specific application configuration settings.

### Computer Systems

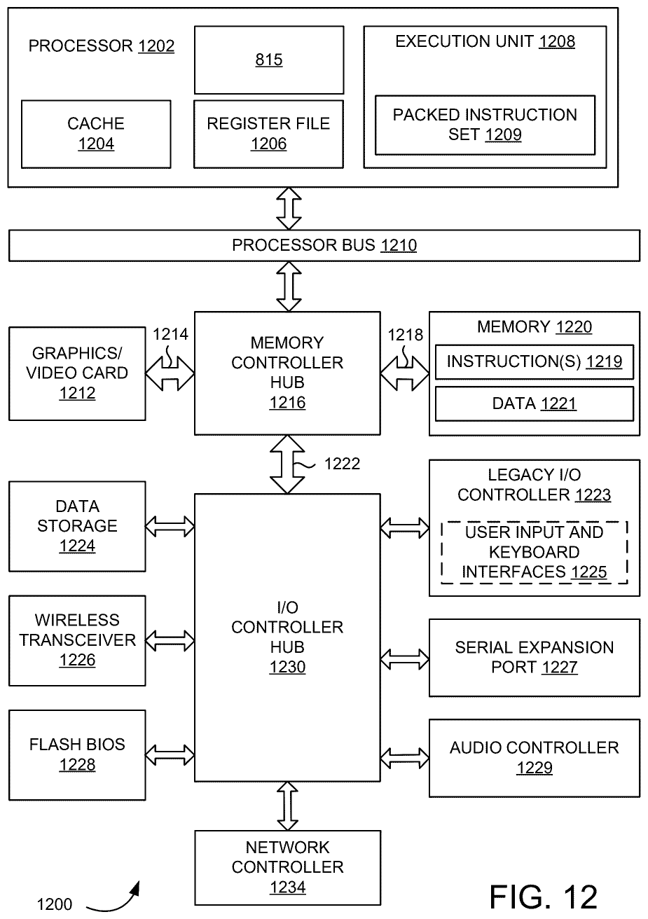

FIG. 12 is a block diagram illustrating an exemplary computer system, which may be a system with interconnected devices and components, a system-on-a-chip (SOC) or some combination thereof formed with a processor that may include execution units to execute an instruction, according to at least one embodiment. In at least one embodiment, a computer system 1200 may include, without limitation, a component, such as a processor 1202 to employ execution units including logic to perform algorithms for process data, in accordance with present disclosure, such as in embodiment described herein. In at least one embodiment, computer system 1200 may include processors, such as PENTIUM® Processor family, Xeon™, Itanium®, XScale™ and/or StrongARM™, Intel® Core™, or Intel® Nervana™ microprocessors available from Intel Corporation of Santa Clara, California, although other systems (including PCs having other microprocessors, engineering workstations, set-top boxes and like) may also be used. In at least one embodiment, computer system 1200 may execute a version of WINDOWS operating system available from Microsoft Corporation of Redmond, Wash., although other operating systems (UNIX and Linux, for example), embedded software, and/or graphical user interfaces, may also be used.

Embodiments may be used in other devices such as handheld devices and embedded applications. Some examples of handheld devices include cellular phones, Internet Protocol devices, digital cameras, personal digital assistants (“PDAs”), and handheld PCs. In at least one embodiment, embedded applications may include a microcontroller, a digital signal processor (“DSP”), system on a chip, network computers (“NetPCs”), set-top boxes, network hubs, wide area network (“WAN”) switches, or any other system that may perform one or more instructions in accordance with at least one embodiment.

In at least one embodiment, computer system 1200 may include, without limitation, processor 1202 that may include, without limitation, one or more execution units 1208 to perform machine learning model training and/or inferencing according to techniques described herein. In at least one embodiment, computer system 1200 is a single processor desktop or server system, but in another embodiment, computer system 1200 may be a multiprocessor system. In at least one embodiment, processor 1202 may include, without limitation, a complex instruction set computer (“CISC”) microprocessor, a reduced instruction set computing (“RISC”) microprocessor, a very long instruction word (“VLIW”) microprocessor, a processor implementing a combination of instruction sets, or any other processor device, such as a digital signal processor, for example. In at least one embodiment, processor 1202 may be coupled to a processor bus 1210 that may transmit data signals between processor 1202 and other components in computer system 1200.

In at least one embodiment, processor 1202 may include, without limitation, a Level 1 (“L1”) internal cache memory (“cache”) 1204. In at least one embodiment, processor 1202 may have a single internal cache or multiple levels of internal cache. In at least one embodiment, cache memory may reside external to processor 1202. Other embodiments may also include a combination of both internal and external caches depending on particular implementation and needs. In at least one embodiment, a register file 1206 may store different types of data in various registers including, without limitation, integer registers, floating point registers, status registers, and an instruction pointer register.

In at least one embodiment, execution unit 1208, including, without limitation, logic to perform integer and floating point operations, also resides in processor 1202. In at least one embodiment, processor 1202 may also include a microcode (“ucode”) read only memory (“ROM”) that stores microcode for certain macro instructions. In at least one embodiment, execution unit 1208 may include logic to handle a packed instruction set 1209. In at least one embodiment, by including packed instruction set 1209 in an instruction set of a general-purpose processor, along with associated circuitry to execute instructions, operations used by many multimedia applications may be performed using packed data in processor 1202. In at least one embodiment, many multimedia applications may be accelerated and executed more efficiently by using a full width of a processor's data bus for performing operations on packed data, which may eliminate a need to transfer smaller units of data across that processor's data bus to perform one or more operations one data element at a time.

In at least one embodiment, execution unit 1208 may also be used in microcontrollers, embedded processors, graphics devices, DSPs, and other types of logic circuits. In at least one embodiment, computer system 1200 may include, without limitation, a memory 1220. In at least one embodiment, memory 1220 may be a Dynamic Random Access Memory (“DRAM”) device, a Static Random Access Memory (“SRAM”) device, a flash memory device, or another memory device. In at least one embodiment, memory 1220 may store instruction(s) 1219 and/or data 1221 represented by data signals that may be executed by processor 1202.

In at least one embodiment, a system logic chip may be coupled to processor bus 1210 and memory 1220. In at least one embodiment, a system logic chip may include, without limitation, a memory controller hub (“MCH”) 1216, and processor 1202 may communicate with MCH 1216 via processor bus 1210. In at least one embodiment, MCH 1216 may provide a high bandwidth memory path 1218 to memory 1220 for instruction and data storage and for storage of graphics commands, data, and textures. In at least one embodiment, MCH 1216 may direct data signals between processor 1202, memory 1220, and other components in computer system 1200 and to bridge data signals between processor bus 1210, memory 1220, and a system I/O interface 1222. In at least one embodiment, a system logic chip may provide a graphics port for coupling to a graphics controller. In at least one embodiment, MCH 1216 may be coupled to memory 1220 through high bandwidth memory path 1218 and a graphics/video card 1212 may be coupled to MCH 1216 through an Accelerated Graphics Port (“AGP”) interconnect 1214.

In at least one embodiment, computer system 1200 may use system I/O interface 1222 as a proprietary hub interface bus to couple MCH 1216 to an I/O controller hub (“ICH”) 1230. In at least one embodiment, ICH 1230 may provide direct connections to some I/O devices via a local I/O bus. In at least one embodiment, a local I/O bus may include, without limitation, a high-speed I/O bus for connecting peripherals to memory 1220, a chipset, and processor 1202. Examples may include, without limitation, an audio controller 1229, a firmware hub (“flash BIOS”) 1228, a wireless transceiver 1226, a data storage 1224, a legacy I/O controller 1223 containing user input and keyboard interfaces 1225, a serial expansion port 1227, such as a Universal Serial Bus (“USB”) port, and a network controller 1234. In at least one embodiment, data storage 1224 may comprise a hard disk drive, a floppy disk drive, a CD-ROM device, a flash memory device, or other mass storage device.

In at least one embodiment, FIG. 12 illustrates a system, which includes interconnected hardware devices or “chips”, whereas in other embodiments, FIG. 12 may illustrate an exemplary SoC. In at least one embodiment, devices illustrated in FIG. 12 may be interconnected with proprietary interconnects, standardized interconnects (e.g., PCIe) or some combination thereof. In at least one embodiment, one or more components of computer system 1200 are interconnected using compute express link (CXL) interconnects.

Inference and/or training logic 815 are used to perform inferencing and/or training operations associated with one or more embodiments. In at least one embodiment, inference and/or training logic 815 may be used in system FIG. 12 for inferencing or predicting operations based, at least in part, on weight parameters calculated using neural network training operations, neural network functions and/or architectures, or neural network use cases described herein.

Embodiments presented herein include cold plates in computer hardware.

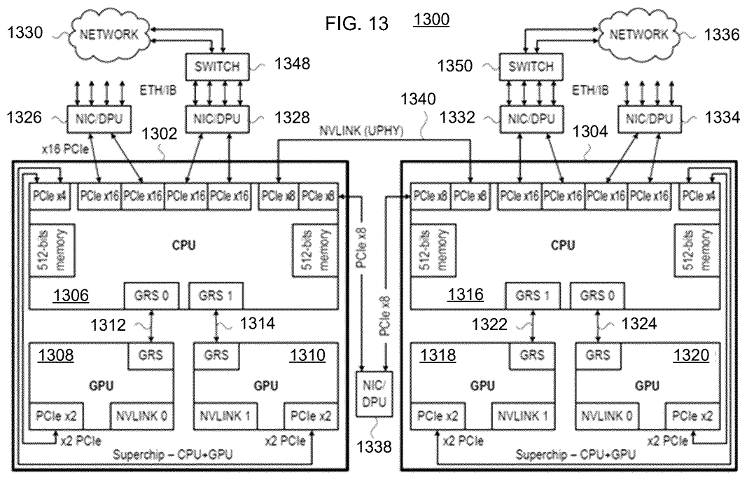

FIG. 13 is a block diagram that schematically illustrates a computing system 1300, e.g., a data center or a High-Performance Computing (HPC) cluster, in accordance with an embodiment that is described herein. System 1300 comprises a plurality of subsystems, e.g. multiple processing devices coupled to each other, multiple network devices, and multiple networks, according to at least one embodiment. Computing system 1300 is designed with multiple integrated circuits (referred to as processing devices), where each integrated circuit can include one or more CPUs and GPUs, forming a powerful and flexible architecture.

The various processing devices are interconnected via an NVLink or other high-speed interconnect, enabling high-speed communication between the subsystems, and are also connected through a NIC or DPU to ensure efficient data transfer across computing system 1300 and to one or more external networks 1330, 1336. In the present example, system 1300 comprises a packet switch 1348 that connects NIC/DPU 1328 to network 1330, and a packet switch 1350 that connects NIC/DPU 1332 to network 1336.

The coupling of processing devices through NVLink allows for seamless data exchange and parallel processing, enhancing overall computational performance. The processing devices are connected to multiple networks through one or more network interface controllers (NICs) or DPUs, enabling the system to handle complex, multi-network tasks with high bandwidth and low latency. This configuration is highly suitable for demanding applications that require significant processing power, such as artificial intelligence (AI), machine learning (ML), and data-intensive computing, while ensuring robust connectivity and scalability across various networked environments. The integrated circuits of the computing system 1300 can include one or more CPUs and one or more GPUs.

FIG. 13 also demonstrates an example architecture of a multi-GPU architecture. As illustrated in the figure, computing system 1300 includes a processing device 1302 with a multi-GPU architecture. In particular, processing device 1302 may be a system-on-chip and includes multiple subsystems such as a CPU 1306, a GPU 1308, and a GPU 1310. CPU 1306 can be coupled to GPU 1308 via a die-to-die (D2D) or chip-to-chip (C2C) interconnect 1312, such as a Ground-Referenced Signaling interconnect (GRS interconnect). CPU 1306 can be coupled to GPU 1310 via a D2D or C2C interconnect 1314. CPU 1306 can also couple to GPU 1308 and GPU 1310 via PCIe interconnects.

CPU 1306 can be coupled to one or more NICs or DPUs, which are coupled to one or more networks. For example, as illustrated in FIG. 13, CPU 1306 is coupled to a first NIC/DPU 1326, which is coupled to a network 1330. CPU 1306 is also coupled to a second NIC/DPU 1328, which is coupled to network 1330 via switch 1348. NIC/DPU 1326 and NIC/DPU 1328 can be coupled to network 1330 over Ethernet (ETH), NVLINK or InfiniBand (IB) connections, for example.

Computing system 1300 also includes a processing device 1304 with a multi-GPU architecture. In particular, processing device 1304 includes multiple subsystems including a CPU 1316, a GPU 1318, and a GPU 1320. CPU 1316 can be coupled to GPU 1318 via an D2D or C2C interconnect 1322. CPU 1316 can be coupled to GPU 1320 via a D2D or C2C interconnect 1324. CPU 1316 can also couple to GPU 1318 and GPU 1320 via PCIe interconnects. CPU 1316 can be coupled to one or more NICs or DPUs, which are coupled to one or more networks. For example, as illustrated in FIG. 13, CPU 1316 is coupled to a first NIC/DPU 1332, which is coupled to a network 1336. CPU 1316 is also coupled to a second NIC/DPU 1334, which is coupled to network 1336 via switch 1350. NIC/DPU 1332 and NIC/DPU 1334 can be coupled to network 1336 over Ethernet (ETH), NVLINK or InfiniBand (IB) connections.

In at least one embodiment, processing device 1302 and processing device 1304 can communication with each other via a NIC/DPU 1338, such as over PCIe interconnects. Processing device 1302 and processing device 1304 can also communicate with each other over a high-bandwidth communication interconnects 1340, such as an NVLink interconnect or other high-speed interconnects. The packet switches in FIG. 13 may comprise, for example, Nvidia Quantum-2 switches. The NICs/DPUs in the figure may comprise, for example, Nvidia Bluefield DPUs.

In various embodiments, any of the network devices of system 1300, e.g., any of NICs/DPUs 1326, 1328, 1332, 1334 and 1338, and/or any of switches 1348 and 1350, may use cold plates in accordance with the techniques described herein.

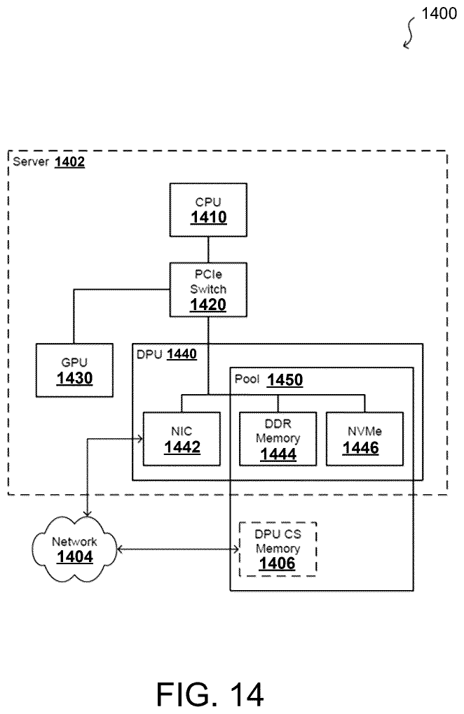

FIG. 14 illustrates an example computing environment 1400 in which forward pass offloading to available memory can be performed, in accordance with at least one embodiment. It should be appreciated that embodiments of the present disclosure may also be used with reference to alternative environments and that specific discussion of components may be provided by way of non-limiting example and may include equivalents. Moreover, various features have been removed for clarity and conciseness. Additionally, systems and methods may be used with a variety of different architectures. The example computing environment 1400 may include a server 1402 which may be used to perform HPC workloads, such as AI training or machine learning model training. In an embodiment, the server 1402 may be an application instance or a compute node. The server 1402 may include a CPU 1410 associated with a switch 1420, such as a peripheral component interconnect express (PCIe) switch, which may control at least some data transmission over communication paths interconnecting various components. In an embodiment, the CPU 1410 may include a root complex processor.

The PCIe switch 1420 may also be associated with a GPU 1430 and a DPU 1440, and may transmit data between at least some of the CPU 1410, the GPU 1430, the DPU 1440, and other components. In an embodiment, the PCIe switch 1420 may be associated with more than one GPU or more than one DPU. In another embodiment, the PCIe switch 1420 may be located within the DPU 1440. The PCIe switch 1420 may manage the transfer of at least some data between the CPU 1410, the GPU 1430, and the DPU 1440. In another embodiment, the number of GPUs associated with the PCIe switch 1420 may be equal to the number of DPUs associated with the PCIe switch 1420. In at least one embodiment, the server 1402 may include, without limitation, any number of the CPUs 1410, the PCIe switches 1420, the GPUs 1430, and/or the DPUs 1440, in any combination. For example, in at least one embodiment, server 1402 could include eight, sixteen, thirty-two, and/or more GPUs 1430. In at least one embodiment, communication paths interconnecting various components, including but not limited to the CPU 1410, the PCIe switch 1420, the GPU 1430, and the DPU 1440, in FIG. 14 may be implemented using any suitable protocols, such as peripheral component interconnect (PCI) based protocols (e.g., PCIe), or other bus or point-to-point communication interfaces and/or protocol(s), such as NV-Link high-speed interconnect, or interconnect protocols.

The DPU 1440 may include a network interface controller (NIC) 1442, a DDR memory 1444, and a non-volatile memory express (NVMe) device 1446. The NIC 1442 may be able to interface with a network 1404, which may also interface with additional NVMe devices available to the DPU 1440, such as over fabric. In an embodiment, the DPU 1440 may not include the NVMe device 1446. In another embodiment, the NVMe device 1446 may be located on the server 1402 and not on the DPU 1440. In yet another embodiment, the computing environment 1400 may include more than one of the NVMe device 1446, such as a first NVMe device in the DPU 1440 and a second first NVMe device on the server 1402 an associated directly with the PCIe switch 1420. In an embodiment, the DPU 1440 may not include the DDR memory 1444 and may include a computational storage services (CSS) in place of, or in addition to, the DDR memory 1444. For example, computing environment 1400 may include DPU computational storage (CS) memory 1406 available to the DPU 1440 as part of the CSS. The network 1404 may be able to interface with the DPU CS memory 1406 through the NIC 1442, according to any suitable interface protocol, such as remote direct memory access (RDMA) over Ethernet, InfiniBand, Fiber Channel, etc.

The total memory of the computing environment 1400 available for data storage may be expanded through the use of the DPU 1440 on nodes of the system. The DPU 1440 may have access to a pool 1450 of memory already available to the server 1402, such as double data rate (DDR) memory, on-board NVMe devices, NVMe devices over fabric, and CS. The pool 1450 of memory may include at least one of the DDR memory 1444, NVMe 1446, and the DPU CS memory 1406. The DPU 1440 may also be able to access the available memory of other DPUs as part of the pool 1450, and other DPUs may be able to access the available memory of DPU 1440, such as the pool 1450. This available memory can be accessed and utilized for data storage, without the addition of compute resources, such as compute nodes, which would be required using other solutions. The available pool 1450 accessible to the DPU 1440 may be provisioned for the server 1402 to expand the total memory available for data storage, such as to reduce the data storage load on the CPU 1410 or the GPU 1430, which can instead increase the utilization of their memory for processing. For example, during training of an AI, the model states, residual states, activation functions, and checkpoints can be stored, or offloaded, on the pool 1450 accessible to the DPU 1440.

### PPU

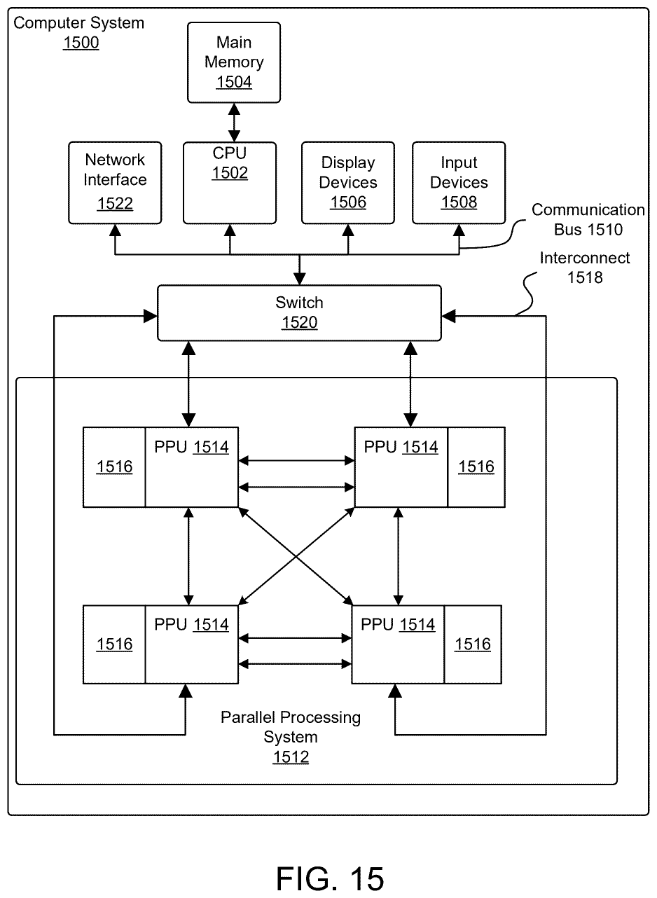

FIG. 15 illustrates a computer system 1500, according to at least one embodiment. In at least one embodiment, computer system 1500 is configured to implement various processes and methods described throughout this disclosure.

In at least one embodiment, computer system 1500 comprises, without limitation, at least one central processing unit (“CPU”) 1502 that is connected to a communication bus 1510 implemented using any suitable protocol, such as PCI (“Peripheral Component Interconnect”), peripheral component interconnect express (“PCI-Express”), AGP (“Accelerated Graphics Port”), HyperTransport, or any other bus or point-to-point communication protocol(s). In at least one embodiment, computer system 1500 includes, without limitation, a main memory 1504 and control logic (e.g., implemented as hardware, software, or a combination thereof) and data are stored in main memory 1504 which may take form of random access memory (“RAM”). In at least one embodiment, a network interface subsystem (“network interface”) 1522 provides an interface to other computing devices and networks for receiving data from and transmitting data to other systems from computer system 1500.

In at least one embodiment, computer system 1500, in at least one embodiment, includes, without limitation, input devices 1508, parallel processing system 1512, and display devices 1506 which can be implemented using a conventional cathode ray tube (“CRT”), liquid crystal display (“LCD”), light emitting diode (“LED”), plasma display, or other suitable display technologies. In at least one embodiment, user input is received from input devices 1508 such as keyboard, mouse, touchpad, microphone, and more. In at least one embodiment, each of foregoing modules can be situated on a single semiconductor platform to form a processing system.

In at least one embodiment, computer programs in form of machine-readable executable code or computer control logic algorithms are stored in main memory 1504 and/or secondary storage. Computer programs, if executed by one or more processors, enable system 1500 to perform various functions in accordance with at least one embodiment. memory 1504, storage, and/or any other storage are possible examples of computer-readable media. In at least one embodiment, secondary storage may refer to any suitable storage device or system such as a hard disk drive and/or a removable storage drive, representing a floppy disk drive, a magnetic tape drive, a compact disk drive, digital versatile disk (“DVD”) drive, recording device, universal serial bus (“USB”) flash memory, etc. In at least one embodiment, architecture and/or functionality of various previous figures are implemented in context of CPU 1502; parallel processing system 1512; an integrated circuit capable of at least a portion of capabilities of both CPU 1502; parallel processing system 1512; a chipset (e.g., a group of integrated circuits designed to work and sold as a unit for performing related functions, etc.); and any suitable combination of integrated circuit(s).

In at least one embodiment, architecture and/or functionality of various previous figures are implemented in context of a general computer system, a circuit board system, a game console system dedicated for entertainment purposes, an application-specific system, and more. In at least one embodiment, computer system 1500 may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

In at least one embodiment, parallel processing system 1512 includes, without limitation, a plurality of parallel processing units (“PPUs”) 1514 and associated memories 1516. In at least one embodiment, PPUs 1514 are connected to a host processor or other peripheral devices via an interconnect 1518 and a switch 1520 or multiplexer. In at least one embodiment, parallel processing system 1512 distributes computational tasks across PPUs 1514 which can be parallelizable—for example, as part of distribution of computational tasks across multiple graphics processing unit (“GPU”) thread blocks. In at least one embodiment, memory is shared and accessible (e.g., for read and/or write access) across some or all of PPUs 1514, although such shared memory may incur performance penalties relative to use of local memory and registers resident to a PPU 1514. In at least one embodiment, operation of PPUs 1514 is synchronized through use of a command such as _syncthreads(), wherein all threads in a block (e.g., executed across multiple PPUs 1514) to reach a certain point of execution of code before proceeding.

Various embodiments can be described by the following clauses:
1. A cooling system for a data center, comprising:
   a cold plate to provide cooling to at least one heat generating device of one or more individual servers of a plurality of servers, the cold plate able to:
   receive a flow of liquid coolant into the individual servers;
   route the received flow of liquid coolant along one or more channels within the cold plate for cooling of the at least one heat generating device directed to corresponding thermal connection positioned along the channels; and
   provide the routed flow of liquid coolant out of the individual servers.
2. The cooling system of clause 1, further comprising:
   one or more pedestals extending from the cold plate at one or more of the thermal connections to thermally interface with the at least one heat generating devices.
3. The cooling system of clause 2, wherein one or more of the pedestals include compressible bellows.
4. The cooling system of clause 1, wherein the one or more channels are adaptable according to the position of the at least one heat generating device.
5. The cooling system of clause 1, wherein the cold plate is further able to provide the flow of liquid coolant to one or more additional components of the servers.
6. The cooling system of clause 1, wherein at least one of the channels include one or more microchannels or fins.
7. The cooling system of clause 6, wherein at least one of the microchannels or fins are copper.
8. The cooling system of clause 1, wherein the flow of liquid coolant is sealed from entering the servers out of the cold plate.
9. A cold plate for a computer system, comprising:
   at least one inlet able to receive from a liquid coolant source external to the computer system;
   one or more internal paths from the at least one inlet to mapped compute device interface locations; and
   at least one outlet able to send from the one or more internal paths to the liquid coolant source external to the computer system.
10. The cold plate of clause 9, further comprising:
   one or more projections positioned along the one or more internal paths and extending above an external surface of the cold plate to interface at one or more of the locations.
11. The cold plate of clause 10, wherein at least one of the projections include bellows to conformably interface at variable distances.
12. The cold plate of clause 9, further comprising:
   one or more inserts on at least an interior surface of the cold plate.
13. The cold plate of clause 12, wherein at least one of the inserts include a microchannels positioned within the cold plate at one of the locations.
14. The cold plate of clause 9, further comprising:
   a leak-resistant barrier between the inlet and the outlet in the computer system.
15. The cold plate of clause 9, wherein the one or more internal paths provide a sole source of cooling from a liquid for the computer system.
16. A method for a liquid-cooled server, comprising:
   determining locations of one or more heat generating devices of the liquid-cooled server;
   configuring at least one cold plate to provide a thermal interface at the locations of the one or more heat generating devices; and
   providing the at least one cold plate to receive a flow of coolant into the liquid-cooled server, provide the received flow to the thermal interface at the locations of the one or more heat generating devices, and send the flow out of the liquid-cooled server.
17. The method for the liquid-cooled server of clause 16, further comprising:
   changing the locations for at least one of the heat generating devices; and
   adapting the at least one cold plate to provide the thermal interface at the changed locations for the one or more heat generating devices.
18. The method for the liquid-cooled server of clause 16, wherein one or more of the thermal interfaces provide at least a portion of the received flow closer to the corresponding heat generating devices.
19. The method for the liquid-cooled server of clause 16, further comprising: including one or more paths fluidly sealed within the at least one cold plate to provide the received flow to the thermal interface.
20. The method for the liquid-cooled server of clause 16, wherein only the at least one cold plate provides a source of cooling from liquid for the liquid-cooled server.

In at least one embodiment, a single semiconductor platform may refer to a sole unitary semiconductor-based integrated circuit or chip. In at least one embodiment, multi-chip modules may be used with increased connectivity which simulate on-chip operation, and make substantial improvements over using a conventional central processing unit (“CPU”) and bus implementation. In at least one embodiment, various modules may also be situated separately or in various combinations of semiconductor platforms per desires of user.

In at least one embodiment, architecture and/or functionality of various previous FIGS. 1-6 are implemented in context of a general computer system, a circuit board system, a game console system dedicated for entertainment purposes, an application-specific system, and more. In at least one embodiment, computer system may take form of a desktop computer, a laptop computer, a tablet computer, servers, supercomputers, a smart-phone (e.g., a wireless, hand-held device), personal digital assistant (“PDA”), a digital camera, a vehicle, a head mounted display, a hand-held electronic device, a mobile phone device, a television, workstation, game consoles, embedded system, and/or any other type of logic.

The systems and methods described herein may be used by, without limitation, non-autonomous vehicles or machines, semi-autonomous or autonomous vehicles or machines (e.g., in one or more advanced driver assistance systems (ADAS), one or more in-vehicle infotainment systems, one or more emergency vehicle detection systems), piloted and un-piloted robots or robotic platforms, warehouse vehicles, off-road vehicles, vehicles coupled to one or more trailers, flying vessels, boats, shuttles, emergency response vehicles, motorcycles, electric or motorized bicycles, aircraft, construction vehicles, trains, underwater craft, remotely operated vehicles such as drones, and/or other vehicle types. Further, the systems and methods described herein may be used for a variety of purposes, by way of example and without limitation, for machine control, machine locomotion, machine driving, synthetic data generation, generative AI, model training or updating, perception, augmented reality, virtual reality, mixed reality, robotics, security and surveillance, simulation and digital twinning, autonomous or semi-autonomous machine applications, deep learning, environment simulation, data center processing, conversational AI, light transport simulation (e.g., ray-tracing, path tracing, etc.), collaborative content creation for 3D assets, generative AI, cloud computing, and/or any other suitable applications.

Disclosed embodiments may be comprised in a variety of different systems such as automotive systems (e.g., an in-vehicle infotainment system for an autonomous or semi-autonomous machine, a perception system for an autonomous or semi-autonomous machine), systems implemented using a robot, aerial systems, medical systems, boating systems, smart area monitoring systems, systems for performing deep learning operations, systems for performing simulation operations, systems for performing digital twin operations, systems implemented using an edge device, systems incorporating one or more virtual machines (VMs), systems for performing synthetic data generation operations, systems implemented at least partially in a data center, systems for performing conversational AI operations, systems implementing one or more language models-- such as large language models (LLMs), systems for performing generative AI operations (e.g., using one or more language models, transformer models, encoder/decoder models, etc.), systems for performing light transport simulation, systems for performing collaborative content creation for 3D assets, systems implemented at least partially using cloud computing resources, and/or other types of systems.

It should be noted that, while example embodiments described herein may relate to a CUDA programming model, techniques described herein can be used with any suitable programming model, such HIP, oneAPI, and/or variations thereof.

Other variations are within spirit of present disclosure. Thus, while disclosed techniques are susceptible to various modifications and alternative constructions, certain illustrated embodiments thereof are shown in drawings and have been described above in detail. It should be understood, however, that there is no intention to limit disclosure to specific form or forms disclosed, but on contrary, intention is to cover all modifications, alternative constructions, and equivalents falling within spirit and scope of disclosure, as defined in appended claims.

Use of terms “a” and “an” and “the” and similar referents in context of describing disclosed embodiments (especially in context of following claims) are to be construed to cover both singular and plural, unless otherwise indicated herein or clearly contradicted by context, and not as a definition of a term. Terms “comprising,” “having,” “including,” and “containing” are to be construed as open-ended terms (meaning “including, but not limited to,”) unless otherwise noted. “Connected,” when unmodified and referring to physical connections, is to be construed as partly or wholly contained within, attached to, or joined together, even if there is something intervening. Recitation of ranges of values herein are merely intended to serve as a shorthand method of referring individually to each separate value falling within range, unless otherwise indicated herein and each separate value is incorporated into specification as if it were individually recited herein. In at least one embodiment, use of term “set” (e.g., “a set of items”) or “subset” unless otherwise noted or contradicted by context, is to be construed as a nonempty collection comprising one or more members. Further, unless otherwise noted or contradicted by context, term “subset” of a corresponding set does not necessarily denote a proper subset of corresponding set, but subset and corresponding set may be equal.

Conjunctive language, such as phrases of form “at least one of A, B, and C,” or “at least one of A, B and C,” unless specifically stated otherwise or otherwise clearly contradicted by context, is otherwise understood with context as used in general to present that an item, term, etc., may be either A or B or C, or any nonempty subset of set of A and B and C. For instance, in illustrative example of a set having three members, conjunctive phrases “at least one of A, B, and C” and “at least one of A, B and C” refer to any of following sets: {A}, {B}, {C}, {A, B}, {A, C}, {B, C}, {A, B, C}. Thus, such conjunctive language is not generally intended to imply that certain embodiments require at least one of A, at least one of B and at least one of C each to be present. In addition, unless otherwise noted or contradicted by context, term “plurality” indicates a state of being plural (e.g., “a plurality of items” indicates multiple items). In at least one embodiment, number of items in a plurality is at least two, but can be more when so indicated either explicitly or by context. Further, unless stated otherwise or otherwise clear from context, phrase “based on” means “based at least in part on” and not “based solely on.”

Operations of processes described herein can be performed in any suitable order unless otherwise indicated herein or otherwise clearly contradicted by context. In at least one embodiment, a process such as those processes described herein (or variations and/or combinations thereof) is performed under control of one or more computer systems configured with executable instructions and is implemented as code (e.g., executable instructions, one or more computer programs or one or more applications) executing collectively on one or more processors, by hardware or combinations thereof. In at least one embodiment, code is stored on a computer-readable storage medium, for example, in form of a computer program comprising a plurality of instructions executable by one or more processors. In at least one embodiment, a computer-readable storage medium is a non-transitory computer-readable storage medium that excludes transitory signals (e.g., a propagating transient electric or electromagnetic transmission) but includes non-transitory data storage circuitry (e.g., buffers, cache, and queues) within transceivers of transitory signals. In at least one embodiment, code (e.g., executable code or source code) is stored on a set of one or more non-transitory computer-readable storage media having stored thereon executable instructions (or other memory to store executable instructions) that, when executed (i.e., as a result of being executed) by one or more processors of a computer system, cause computer system to perform operations described herein. In at least one embodiment, set of non-transitory computer-readable storage media comprises multiple non-transitory computer-readable storage media and one or more of individual non-transitory storage media of multiple non-transitory computer-readable storage media lack all of code while multiple non-transitory computer-readable storage media collectively store all of code. In at least one embodiment, executable instructions are executed such that different instructions are executed by different processors—for example, a non-transitory computer-readable storage medium store instructions and a main central processing unit (“CPU”) executes some of instructions while a graphics processing unit (“GPU”) executes other instructions. In at least one embodiment, different components of a computer system have separate processors and different processors execute different subsets of instructions.

In at least one embodiment, an arithmetic logic unit is a set of combinational logic circuitry that takes one or more inputs to produce a result. In at least one embodiment, an arithmetic logic unit is used by a processor to implement mathematical operation such as addition, subtraction, or multiplication. In at least one embodiment, an arithmetic logic unit is used to implement logical operations such as logical AND/OR or XOR. In at least one embodiment, an arithmetic logic unit is stateless, and made from physical switching components such as semiconductor transistors arranged to form logical gates. In at least one embodiment, an arithmetic logic unit may operate internally as a stateful logic circuit with an associated clock. In at least one embodiment, an arithmetic logic unit may be constructed as an asynchronous logic circuit with an internal state not maintained in an associated register set. In at least one embodiment, an arithmetic logic unit is used by a processor to combine operands stored in one or more registers of the processor and produce an output that can be stored by the processor in another register or a memory location.

In at least one embodiment, as a result of processing an instruction retrieved by the processor, the processor presents one or more inputs or operands to an arithmetic logic unit, causing the arithmetic logic unit to produce a result based at least in part on an instruction code provided to inputs of the arithmetic logic unit. In at least one embodiment, the instruction codes provided by the processor to the ALU are based at least in part on the instruction executed by the processor. In at least one embodiment combinational logic in the ALU processes the inputs and produces an output which is placed on a bus within the processor. In at least one embodiment, the processor selects a destination register, memory location, output device, or output storage location on the output bus so that clocking the processor causes the results produced by the ALU to be sent to the desired location.

In the scope of this application, the term arithmetic logic unit, or ALU, is used to refer to any computational logic circuit that processes operands to produce a result. For example, in the present document, the term ALU can refer to a floating point unit, a DSP, a tensor core, a shader core, a coprocessor, or a CPU.

Accordingly, in at least one embodiment, computer systems are configured to implement one or more services that singly or collectively perform operations of processes described herein and such computer systems are configured with applicable hardware and/or software that enable performance of operations. Further, a computer system that implements at least one embodiment of present disclosure is a single device and, in another embodiment, is a distributed computer system comprising multiple devices that operate differently such that distributed computer system performs operations described herein and such that a single device does not perform all operations.

Use of any and all examples, or exemplary language (e.g., “such as”) provided herein, is intended merely to better illuminate embodiments of disclosure and does not pose a limitation on scope of disclosure unless otherwise claimed. No language in specification should be construed as indicating any non-claimed element as essential to practice of disclosure.

In description and claims, terms “coupled” and “connected,” along with their derivatives, may be used. It should be understood that these terms may be not intended as synonyms for each other. Rather, in particular examples, “connected” or “coupled” may be used to indicate that two or more elements are in direct or indirect physical or electrical contact with each other. “Coupled” may also mean that two or more elements are not in direct contact with each other, but yet still co-operate or interact with each other.

Unless specifically stated otherwise, it may be appreciated that throughout specification terms such as “processing,” “computing,” “calculating,” “determining,” or like, refer to action and/or processes of a computer or computing system, or similar electronic computing device, that manipulate and/or transform data represented as physical, such as electronic, quantities within computing system's registers and/or memories into other data similarly represented as physical quantities within computing system's memories, registers or other such information storage, transmission or display devices.

In a similar manner, term “processor” may refer to any device or portion of a device that processes electronic data from registers and/or memory and transform that electronic data into other electronic data that may be stored in registers and/or memory. As non-limiting examples, “processor” may be a CPU or a GPU. A “computing platform” may comprise one or more processors. As used herein, “software” processes may include, for example, software and/or hardware entities that perform work over time, such as tasks, threads, and intelligent agents. Also, each process may refer to multiple processes, for carrying out instructions in sequence or in parallel, continuously or intermittently. In at least one embodiment, terms “system” and “method” are used herein interchangeably insofar as system may embody one or more methods and methods may be considered a system.

In present document, references may be made to obtaining, acquiring, receiving, or inputting analog or digital data into a subsystem, computer system, or computer-implemented machine. In at least one embodiment, process of obtaining, acquiring, receiving, or inputting analog and digital data can be accomplished in a variety of ways such as by receiving data as a parameter of a function call or a call to an application programming interface. In at least one embodiment, processes of obtaining, acquiring, receiving, or inputting analog or digital data can be accomplished by transferring data via a serial or parallel interface. In at least one embodiment, processes of obtaining, acquiring, receiving, or inputting analog or digital data can be accomplished by transferring data via a computer network from providing entity to acquiring entity. In at least one embodiment, references may also be made to providing, outputting, transmitting, sending, or presenting analog or digital data. In various examples, processes of providing, outputting, transmitting, sending, or presenting analog or digital data can be accomplished by transferring data as an input or output parameter of a function call, a parameter of an application programming interface or interprocess communication mechanism.

Although descriptions herein set forth example implementations of described techniques, other architectures may be used to implement described functionality, and are intended to be within scope of this disclosure. Furthermore, although specific distributions of responsibilities may be defined above for purposes of description, various functions and responsibilities might be distributed and divided in different ways, depending on circumstances.

Furthermore, although subject matter has been described in language specific to structural features and/or methodological acts, it is to be understood that subject matter claimed in appended claims is not necessarily limited to specific features or acts described. Rather, specific features and acts are disclosed as exemplary forms of implementing the claims.

What is claimed is:

1. A cooling system for a data center, comprising:
a cold plate to provide cooling to at least one heat generating device of one or more individual servers of a plurality of servers, the cold plate able to:
receive a flow of liquid coolant into the individual servers;
route the received flow of liquid coolant along one or more channels within the cold plate for cooling of the at least one heat generating device directed to corresponding thermal connection positioned along the channels; and
provide the routed flow of liquid coolant out of the individual servers.

2. The cooling system of claim 1, further comprising:
one or more pedestals extending from the cold plate at one or more of the thermal connections to thermally interface with the at least one heat generating devices.

3. The cooling system of claim 2, wherein one or more of the pedestals include compressible bellows.

4. The cooling system of claim 1, wherein the one or more channels are adaptable according to the position of the at least one heat generating device.

5. The cooling system of claim 1, wherein the cold plate is further able to provide the flow of liquid coolant to one or more additional components of the servers.

6. The cooling system of claim 1, wherein at least one of the channels include one or more microchannels or fins.

7. The cooling system of claim 6, wherein at least one of the microchannels or fins are copper.

8. The cooling system of claim 1, wherein the flow of liquid coolant is sealed from entering the servers out of the cold plate.

9. A cold plate for a computer system, comprising:
at least one inlet able to receive from a liquid coolant source external to the computer system;
one or more internal paths from the at least one inlet to mapped compute device interface locations; and
at least one outlet able to send from the one or more internal paths to the liquid coolant source external to the computer system.

10. The cold plate of claim 9, further comprising:
one or more projections positioned along the one or more internal paths and extending above an external surface of the cold plate to interface at one or more of the locations.

11. The cold plate of claim 10, wherein at least one of the projections include bellows to conformably interface at variable distances.

12. The cold plate of claim 9, further comprising:
one or more inserts on at least an interior surface of the cold plate.

13. The cold plate of claim 12, wherein at least one of the inserts include a microchannels positioned within the cold plate at one of the locations.

14. The cold plate of claim 9, further comprising:
a leak-resistant barrier between the inlet and the outlet in the computer system.

15. The cold plate of claim 9, wherein the one or more internal paths provide a sole source of cooling from a liquid for the computer system.

16. A method for a liquid-cooled server, comprising:
determining locations of one or more heat generating devices of the liquid-cooled server;
configuring at least one cold plate to provide a thermal interface at the locations of the one or more heat generating devices; and
providing the at least one cold plate to receive a flow of coolant into the liquid-cooled server, provide the received flow to the thermal interface at the locations of the one or more heat generating devices, and send the flow out of the liquid-cooled server.

17. The method for the liquid-cooled server of claim 16, further comprising:
changing the locations for at least one of the heat generating devices; and
adapting the at least one cold plate to provide the thermal interface at the changed locations for the one or more heat generating devices.

18. The method for the liquid-cooled server of claim 16, wherein one or more of the thermal interfaces provide at least a portion of the received flow closer to the corresponding heat generating devices.

19. The method for the liquid-cooled server of claim 16, further comprising:
including one or more paths fluidly sealed within the at least one cold plate to provide the received flow to the thermal interface.

20. The method for the liquid-cooled server of claim 16, wherein only the at least one cold plate provides a source of cooling from liquid for the liquid-cooled server.
